(19) United States
(12) Patent Application Publication
(10) Pub. No.: US 2026/0173618 A1
(43) Pub. Date: Jun. 18, 2026

(54) DISPLAY DEVICE, REPAIRING METHOD OF DISPLAY DEVICE, AND ELECTRONIC APPARATUS INCLUDING THE SAME

(71) Applicant: Samsung Display Co., LTD., Yongin-si (KR)

(72) Inventors: Changil TAE, Yongin-si (KR); Gyujeong LEE, Yongin-si (KR); Jaeyeon JEONG, Yongin-si (KR)

(21) Appl. No.: 19/424,649

(22) Filed: Dec. 18, 2025

(30) Foreign Application Priority Data
Dec. 18, 2024 (KR) 10-2024-0190450

(51) Int. Cl. H10H 29/49; H10H 29/01

(52) U.S. Cl. CPC H10H 29/49; H10H 29/012

(57) ABSTRACT

A display device includes a first electrode pad and a second electrode pad apart from each other over a substrate, a first light-emitting element on the first electrode pad and the second electrode pad and electrically connected to the first electrode pad and the second electrode pad, a conductive pattern between the substrate and the first electrode pad, and a first insulating layer between the conductive pattern and the first electrode pad. A portion of the first electrode pad overlaps the conductive pattern, a width of the portion of the first electrode pad is less than a width of a first portion of the first electrode pad overlapping the first light-emitting element, and a width of a first connection portion of the display device is less than the width of the first portion.

This application claims priority to Korean Patent Application No. 10-2024-0190450, filed on Dec. 18, 2024, and all the benefits accruing therefrom under 35 U.S.C. § 119, the content of which in its entirety is herein incorporated by reference.

### 1. FIELD

Embodiments of the disclosure relate to a display device, a repairing method of the display device, and an electronic apparatus including the same.

### 2. Description of the Related Art

As display device that visually display various electrical signals develop, various display device having excellent characteristics such as being slim, being lightweight, having relatively low power consumption, and the like are being introduced. As an example, flexible display device that are foldable or rollable in a roll shape are being introduced. Recently, research and development into display device of various structures, such as stretchable display device that may change into various shapes are actively in progress.

### SUMMARY

Embodiments of the disclosure provide a display device, a repairing method of the display device, and an electronic apparatus including the same.

An embodiment of the disclosure discloses a display device including: a first electrode pad and a second electrode pad apart from each other on a substrate; a first light-emitting element on the first electrode pad and the second electrode pad, the first light-emitting element electrically connected to the first electrode pad and the second electrode pad; a conductive pattern between the substrate and the first electrode pad; and a first insulating layer between the conductive pattern and the first electrode pad, where a portion of the first electrode pad overlaps the conductive pattern, and a width of the portion of the first electrode pad is less than a width of a first portion of the first electrode pad overlapping the first light-emitting element.

In an embodiment, the conductive pattern may have a same voltage level as the second electrode pad.

In an embodiment, the display device may further include: a common voltage line on the substrate and electrically connected to the second electrode pad; and a second insulating layer between the common voltage line and the conductive pattern, where the common voltage line may be electrically connected to the conductive pattern through a contact hole defined in the second insulating layer.

In an embodiment, a portion of the second electrode pad may overlap the conductive pattern, and a width of the portion of the second electrode pad may be less than a width of a first portion of the second electrode pad.

In an embodiment, the display device may further include: a transistor on the substrate; another first electrode pad next (adjacent) to the first electrode pad; another second electrode pad apart from the another first electrode pad; and a second light-emitting element on the another first electrode pad and the another second electrode pad, the second light-emitting element electrically connected to the another first electrode pad and the another second electrode pad, where the another first electrode pad may include: a first portion overlapping the second light-emitting element; and a second portion electrically connected to the transistor, and where the first portion and the second portion of the another first electrode pad may be separated from each other.

In an embodiment, the second light-emitting element may be in an off-state.

In an embodiment, a portion of the first insulating layer corresponding to a separation region between the first portion and the second portion of the another first electrode pad may include a concave portion.

In an embodiment, a bottom surface of the concave portion may be spaced apart from an upper surface of the conductive pattern.

In an embodiment, the concave portion may extend up to an upper surface of the conductive pattern, and the first portion or the second portion of the another first electrode pad may be in direct contact with the upper surface of the conductive pattern.

The disclosure is a repairing method of a display device, where the display device includes: a transistor on a substrate; a first electrode pad electrically connected to the transistor; a second electrode pad apart from the first electrode pad; a light-emitting element disposed on the first electrode pad and the second electrode pad and electrically connected to the first electrode pad and the second electrode pad; a conductive pattern between the substrate and the first electrode pad; and a first insulating layer between the conductive pattern and the first electrode pad, where the method includes irradiating a laser to a portion of the first electrode pad such that a first portion of the first electrode pad electrically connected to the light-emitting element and a second portion of the first electrode pad electrically connected to the transistor are separated from each other.

In an embodiment, a width of the portion of the first electrode pad to which the laser is irradiated may be less than a width of the first portion of the first electrode pad.

In an embodiment, in the irradiating the laser, the portion of the first electrode pad may overlap the conductive pattern.

In an embodiment, in the irradiating the laser, a width of the portion of the first electrode pad may be less than a width of the first portion or a width of the second portion of the first electrode pad.

In an embodiment, the conductive pattern may have a same voltage level as the second electrode pad.

An embodiment of the disclosure discloses an electronic apparatus including a display device, where the display device includes: a first electrode pad and a second electrode pad apart from each other over a substrate; a first light-emitting element on the first electrode pad and the second electrode pad and electrically connected to the first electrode pad and the second electrode pad; a conductive pattern between the substrate and the first electrode pad; and a first insulating layer between the conductive pattern and the first electrode pad, and where a width of a portion of the first electrode pad is less than a width of a first portion of the first electrode pad overlapping the first light-emitting element.

In an embodiment, the conductive pattern may have a same voltage level as the second electrode pad.

In an embodiment, the display device may further include: a common voltage line disposed on the substrate and electrically connected to the second electrode pad; and a second insulating layer between the common voltage line and the conductive pattern, where the common voltage line may be electrically connected to the conductive pattern through a contact hole defined in the second insulating layer.

In an embodiment, the portion of the first electrode pad may overlap the conductive pattern.

In an embodiment, the display device may further include: a transistor on the substrate; another first electrode pad next (adjacent) to the first electrode pad; another second electrode pad apart from the another first electrode pad; and a second light-emitting element on the another first electrode pad and the another second electrode pad, the second light-emitting element electrically connected to the another first electrode pad and the another second electrode pad, where the another first electrode pad may include: a first portion overlapping the second light-emitting element; and a second portion electrically connected to the transistor, and where the first portion and the second portion of the another first electrode pad may be separated from each other.

In an embodiment, a portion of the first insulating layer corresponding to a separation region between the first portion and the second portion of the another first electrode pad may include a concave portion.

In an embodiment of the disclosure, a repair process capable of preventing an issue of unexpected defects, a display device and an electronic apparatus including the same may be provided.

This effect is an example, and the scope of the disclosure is not limited by the effect.

### BRIEF DESCRIPTION OF DRAWINGS

The above and other embodiments, advantages and features of this disclosure will become more apparent by describing in further detail embodiments thereof with reference to the accompanying drawings.

FIG. 1 is a schematic perspective view of an embodiment of a display device according to the disclosure.

FIGS. 2A and 2B are perspective views of the display device of FIG. 1 in a state stretched in a first direction.

FIG. 2C is a perspective view of the display device of FIG. 1 in a state stretched in a second direction.

FIG. 2D is a perspective view of the display device of FIG. 1 in a state stretched in the first direction and the second direction.

FIG. 2E is a perspective view of the display device of FIG. 1 in a state stretched in a third direction.

FIG. 3 is a schematic plan view of an embodiment of a display device according to the disclosure.

FIG. 4A is an enlarged plan view of an embodiment of a portion of a display device, showing a region IV of FIG. 3 according to the disclosure.

FIG. 4B is an enlarged plan view of an embodiment of a portion of a display device, showing a region IV of FIG. 3 according to the disclosure.

FIG. 4C is an enlarged plan view of a portion of an embodiment of a display device, showing a region IV of FIG. 3 according to the disclosure.

FIG. 4D is an enlarged plan view of an embodiment of a portion of the display device 1, showing the display area DA of FIG. 3 according to the disclosure.

FIG. 4E is an enlarged plan view of an embodiment of a portion of the display device, showing a region IV of FIG. 3 according to the disclosure.

FIG. 5 is a schematic cross-sectional view of an embodiment of a first island portion and a first bridge portion disposed in a display area of a display device according to the disclosure.

FIGS. 6A to 6C are equivalent circuit diagrams of an embodiment of a sub-pixel of a display device according to the disclosure.

FIG. 7 is an excerpted plan view of an embodiment of a portion of a display area of a display device according to the disclosure.

FIG. 8 is a cross-sectional view of an embodiment of a portion of a display area of a display device, taken along line VIII-VIII′ of FIG. 7, according to the disclosure.

FIG. 9 is an excerpted plan view of an embodiment of a portion of a display area of a display device according to the disclosure.

FIG. 10A is a plan view to explain an embodiment of a repair process of a display device according to the disclosure.

FIG. 10B is a cross-sectional view of an embodiment of a structure of a display device by a repair process of a display device according to the disclosure.

FIG. 10C is an enlarged view of a region Xc of FIG. 10B.

FIG. 11 is a cross-sectional view of an embodiment of a structure of a display device by a repair process of a display device according to the disclosure.

FIG. 12 is a schematic cross-sectional view of an embodiment of a display device by a repair process of a display device according to the disclosure.

FIG. 13A is a schematic perspective view of an embodiment of an electronic apparatus including a display device according to the disclosure.

FIG. 13B is a schematic block diagram of an embodiment of an electronic apparatus including a display device according to the disclosure.

FIGS. 14A to 14I are respectively schematic perspective views of an embodiment of an electronic apparatus including a display device according to the disclosure.

### DETAILED DESCRIPTION

As the disclosure allows for various changes and numerous embodiments, illustrative embodiments will be illustrated in the drawings and described in the detailed description. Effects and features of the disclosure, and methods for achieving them will be clarified with reference to embodiments described below with reference to the drawings. However, the disclosure is not limited to embodiments described below and may be implemented in various forms.

Hereinafter, embodiments of the disclosure will be described with reference to the accompanying drawings, where like or corresponding elements are given like reference characters when describing with reference to the drawings, and a repeated description thereof is omitted.

While such terms as “first” and “second” may be used to describe various elements, such elements must not be limited to the above terms. The above terms are used to distinguish one element from another element.

In an embodiment below, the singular expressions include the plural expressions unless the context clearly indicates otherwise.

In an embodiment below, the terms such as “comprise” or “have” specify the presence of stated features or elements described in the specification but do not preclude the possibility of the addition of one or more other features or elements.

In an embodiment below, when a layer, region, or element is referred to as being on another portion, it may include not only a case where the layer, region, or element is directly on the another portion, but also a case where intervening layers, regions, or elements are disposed therebetween.

Sizes of elements in the drawings may be exaggerated or reduced for convenience of explanation. In an embodiment, the size and thickness of each element shown in the drawings are arbitrarily represented for convenience of description, and thus, the disclosure is not necessarily limited thereto.

In the case where an illustrative embodiment may be implemented differently, a predetermined process order may be performed in the order different from the described order. In an embodiment, two processes successively described may be simultaneously performed substantially and performed in the opposite order of the described order.

In the specification, “A and/or B” means A or B, or A and B. In addition, “at least one of A and B” means A or B, or A and B.

In an embodiment below, when a layer, region, or element is referred to as being connected, it includes not only a case where the layer, region, or element is directly connected, but also a case where the layer, region, or element is indirectly connected with another layer, region, or element disposed therebetween. For example, in the specification, when a layer, region, or element is referred to as being electrically connected, it represents a case where the layer, region, or element is directly electrically connected and/or a case where the layer, region, or element may be indirectly electrically connected with another layer, region, or element disposed therebetween.

The x-axis, the y-axis and the z-axis are not limited to three axes of the rectangular coordinate system, and may be interpreted in a broader sense including the same. For example, x axis, y axis, and z axis may be perpendicular to one another, or may represent different directions that are not perpendicular to one another.

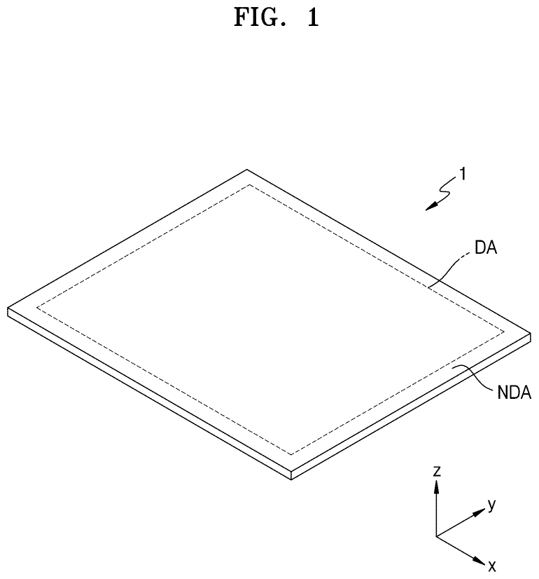

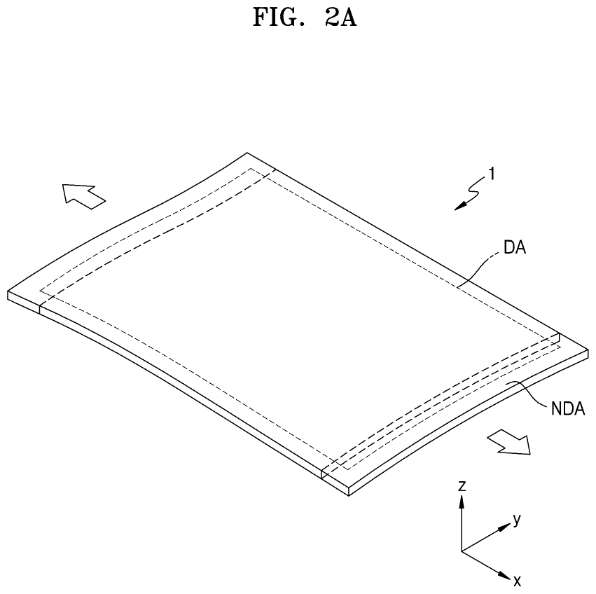

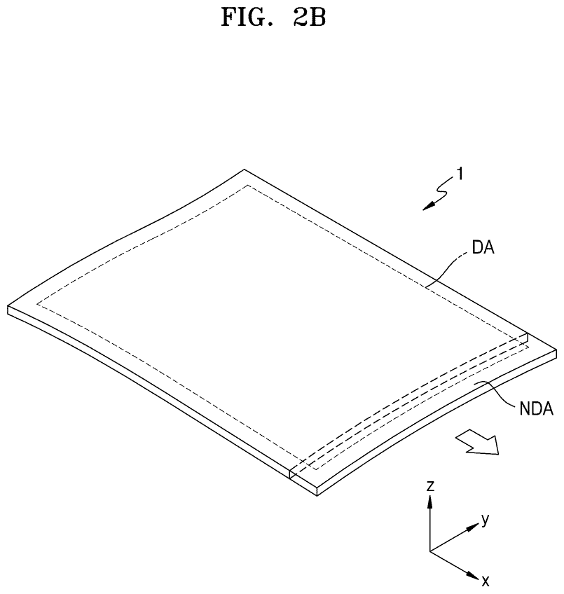

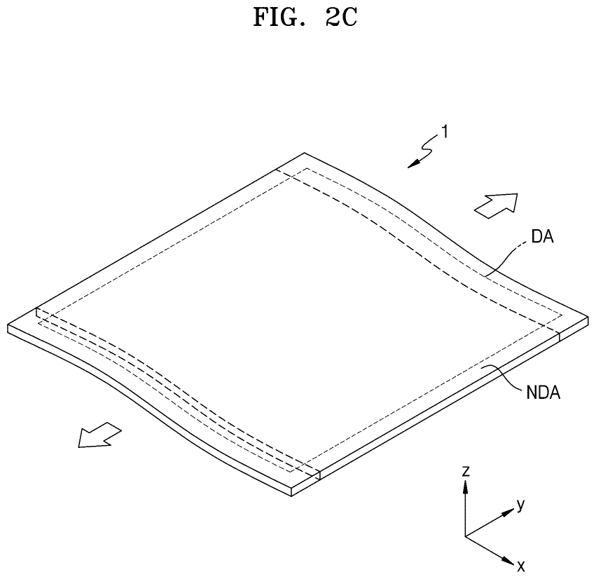

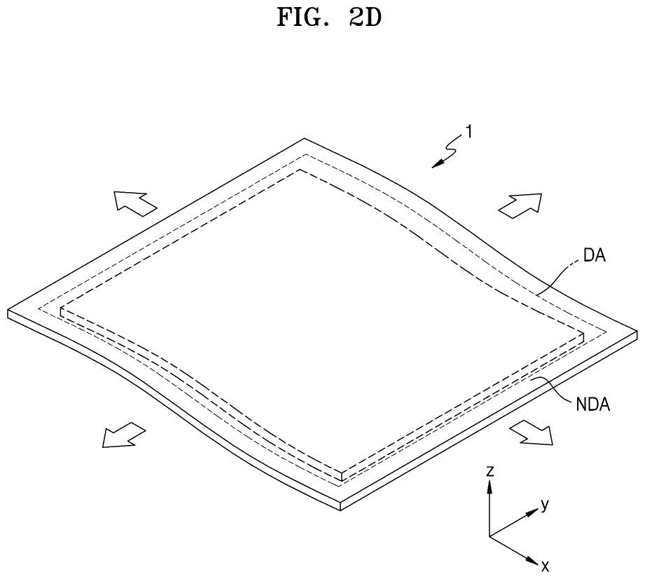

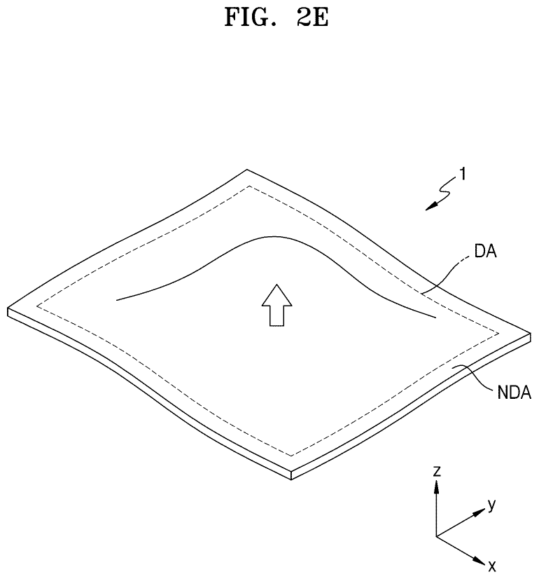

FIG. 1 is a schematic perspective view of an embodiment of a display device 1 according to the disclosure. FIGS. 2A and 2B are perspective views of the display device 1 of FIG. 1 in a state stretched in a first direction. FIG. 2C is a perspective view of the display device 1 of FIG. 1 in a state stretched in a second direction. FIG. 2D is a perspective view of the display device of FIG. 1 in a state stretched in the first direction and the second direction. FIG. 2E is a perspective view of the display device 1 of FIG. 1 in a state stretched in a third direction.

Referring to FIG. 1, the display device 1 may include a display area DA and a non-display area NDA. The display area DA may include a plurality of pixels. The display device 1 may provide preset images by light emitted from the plurality of pixels. The non-display area NDA may be disposed outside the display area DA. The non-display area NDA is a region in which the pixels are not disposed and may surround the display area DA entirely.

The display device 1 may be stretched or contracted in various directions. The display device 1 may be stretched in the first direction (e.g., x direction and/or −x direction) by external force exerted by an external object or a user. In an embodiment, as shown in FIGS. 2A and 2B, the display area DA and/or the non-display area NDA of the display device 1 may be stretched in the first direction (e.g., x direction and/or −x direction). In an embodiment, as shown in FIG. 2A, the display area DA and/or the non-display area NDA may be stretched in the x direction and −x direction, or as shown in FIG. 2B, be stretched in the x direction with one side of the display device 1 fixed.

The display device 1 may be stretched in the second direction (e.g., y direction and/or −y direction) by external force exerted by an external object or a user. In an embodiment, as shown in FIG. 2C, the display area DA and/or the non-display area NDA of the display device 1 may be stretched in the y direction and −y direction. In another embodiment, the display device 1 may be stretched in the y direction or −y direction with one side of the display device 1 fixed.

The display device 1 may be stretched in a plurality of directions, e.g., the first direction (e.g., x direction and/or −x direction) and the second direction (e.g., y direction and/or −y direction) by external force exerted by an external object or a portion of a person's body. As shown in FIG. 2D, the display area DA and/or the non-display area NDA of the display device 1 may be stretched in a ±x direction and ±y direction.

The display device 1 may be stretched in a third direction (e.g., z direction and/or −z direction) by external force exerted by an external object or a portion of a person's body. In an embodiment, FIG. 2E shows a portion of the display device 1, e.g., a partial region of the display area DA protrudes in the z direction. In another embodiment, a portion of the display device 1, e.g., a partial region of the display area DA may protrude in the −z direction (or be recessed in the z direction).

Although it is shown in FIGS. 2A to 2E that the display device 1 is stretched in the first direction, the second direction, and/or the third direction, the disclosure is not limited thereto. In another embodiment, the display device 1 may be variously transformed into an irregular shape, such as being bent or twisted along two or more axes.

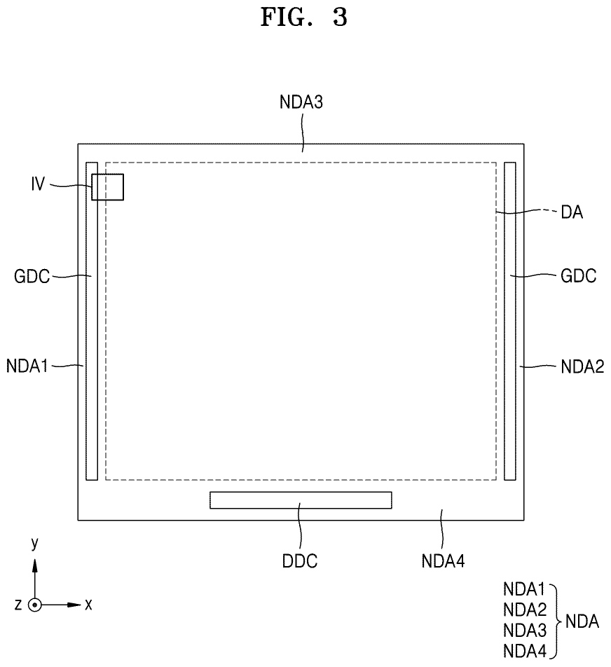

FIG. 3 is a schematic plan view of an embodiment of the display device 1 according to the disclosure.

The plurality of pixels may be arranged in the display area DA of the display device 1. Each pixel may include sub-pixels emitting light of different colors. A light-emitting element corresponding to each sub-pixel may be disposed in the display area DA. A circuit may be disposed in the non-display area NDA around the display area DA, where the circuit provides electrical signals to light-emitting elements disposed in the display area DA and transistors electrically connected to the light-emitting elements. A gate driving circuit GDC may be disposed in each of a first non-display area NDA1 and a second non-display area NDA2 disposed on two opposite sides with the display area DA therebetween. The gate driving circuit GDC may include drivers for providing electrical signals to a gate electrode of each of transistors electrically connected to light-emitting elements. Although it is shown in FIG. 3 that the gate driving circuit GDC is disposed in each of the first non-display area NDA1 and the second non-display area NDA2, the disclosure is not limited thereto. In another embodiment, the gate driving circuit GDC may be disposed in one of the first non-display area NDA1 and the second non-display area NDA2.

A data driving circuit DDC may be disposed in a third non-display area NDA3 and/or a fourth non-display area NDA4 connecting the first non-display area NDA1 and the second non-display area NDA2 to each other. In an embodiment, it is shown in FIG. 3 that the data driving circuit DDC is disposed in the fourth non-display area NDA4. In another embodiment, the data driving circuit DDC may be disposed in each of the third non-display area NDA3 and fourth non-display area NDA4.

Although it is shown in FIG. 3 that the data driving circuit DDC is disposed in the fourth non-display area NDA4 of the display device 1, the disclosure is not limited thereto. In another embodiment, the display device 1 may further include a flexible circuit board (not shown) electrically connected through a terminal section (not shown) disposed in the fourth non-display area NDA4, and the data driving circuit DDC may be disposed on the flexible circuit board.

In another embodiment, an elongation of the non-display area NDA may be equal to or less than an elongation of the display area DA. In an embodiment, an elongation of the non-display area NDA may be different for each region. In an embodiment, the first non-display area NDA1, the second non-display area NDA2, and the third non-display area NDA3 may have substantially the same elongation, but an elongation of the fourth non-display area NDA4 may be less than an elongation of each of the first non-display area NDA1, the second non-display area NDA2, and the third non-display area NDA3. In t he specification, an elongation is a numerical value representing a change ΔL/L in length by which the display device 1 may be stretched without physical damage to the display device 1 when external force is applied to the display device 1. Here, ΔL is the amount of change in length of the display device 1, and L represents an initial length of the display device 1.

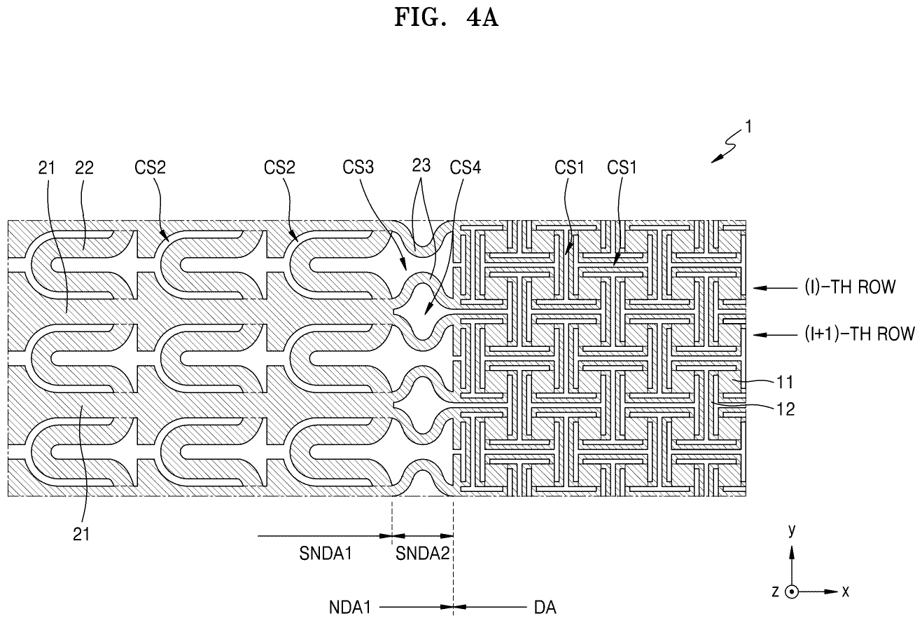

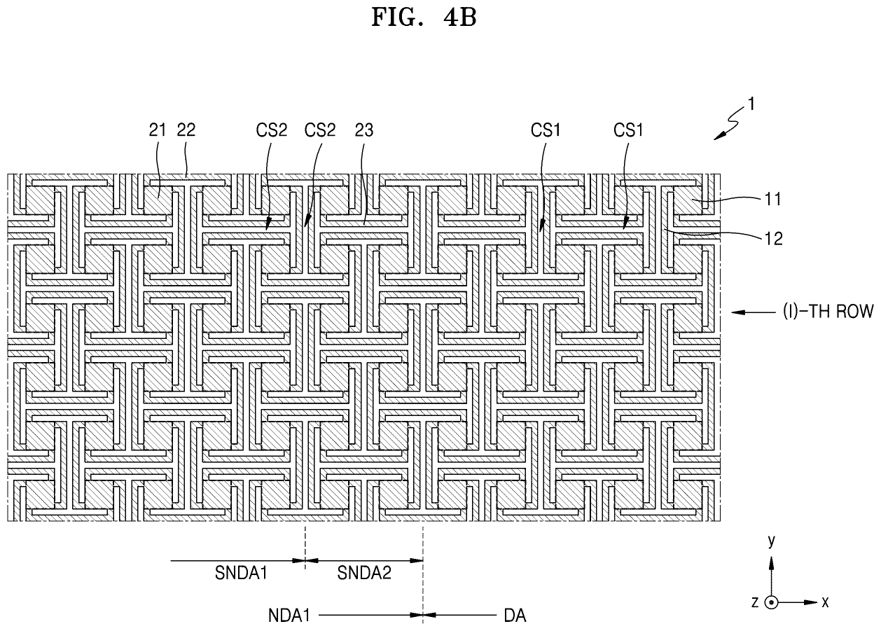

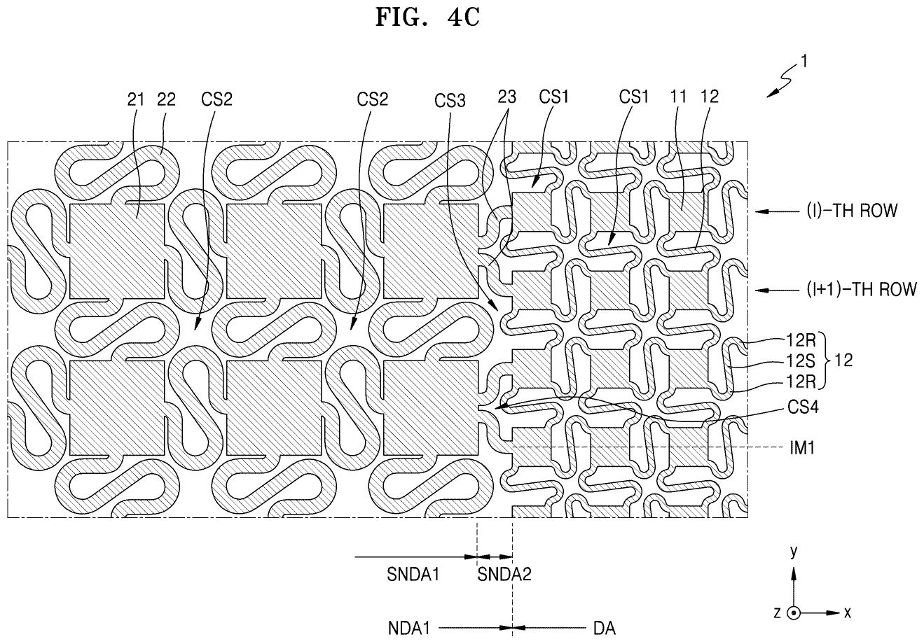

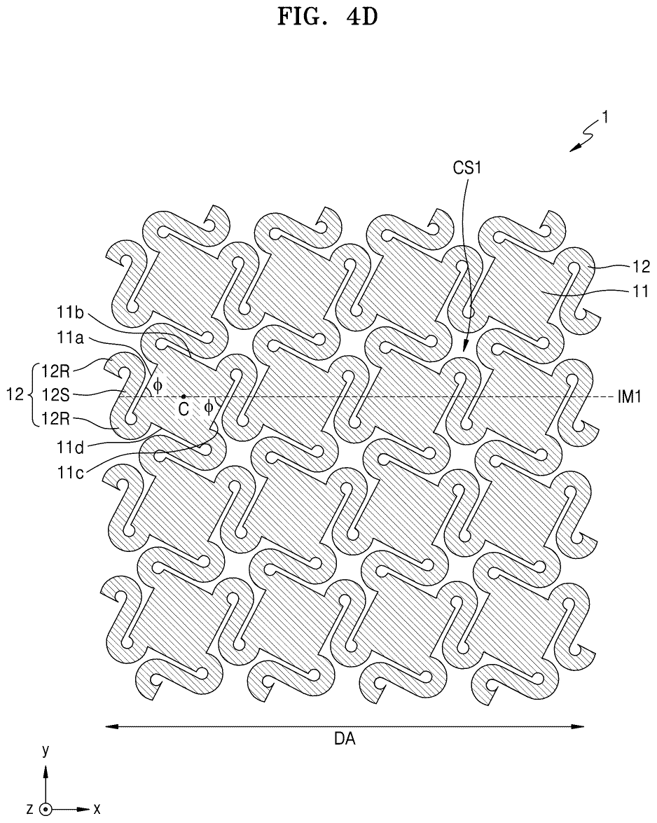

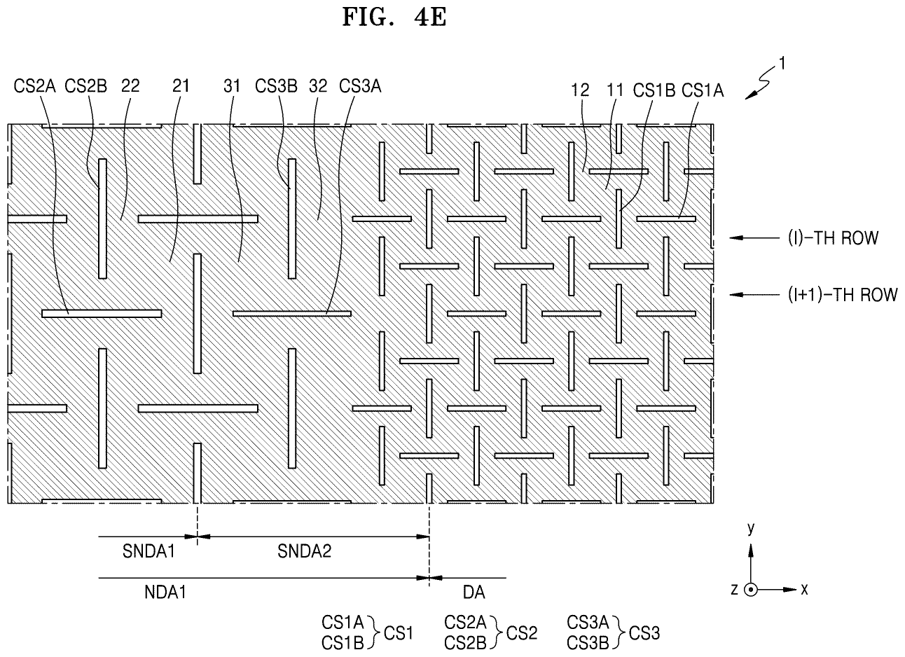

FIG. 4A is an enlarged plan view of an embodiment of a portion of the display device 1, showing a region IV of FIG. 3 according to the disclosure.

Referring to FIG. 4A, the display device 1 may include first island portions 11 and first bridge portions 12 connecting first island portions 11 next (adjacent) to each other, where the first island portions 11 are spaced apart from each other in the first direction (e.g., x direction or −x direction) and the second direction (e.g., y direction or −y direction) in the display area DA.

Each first island portion 11 may be connected to a plurality of first bridge portions 12. In an embodiment, each first island portion 11 may be connected to four first bridge portions 12. Two first bridge portions 12 may be disposed on two opposite sides of the first island portion 11 in the first direction (e.g., x direction or −x direction), and the remaining two first bridge portions 12 may be disposed on two opposite sides of the first island portion 11 in the second direction (e.g., y direction or −y direction). In an embodiment, four first bridge portions 12 may be respectively connected to four sides of the first island portion 11. Four first bridge portions 12 may be respectively next (adjacent) to the corners of the first island portion 11.

The first bridge portions 12 may be spaced apart from each other by a first opening CS1 defined between the first bridge portions 12. In an embodiment, the first opening CS1 having an approximate H shape and a first opening CS1 having an approximate I shape that is obtained by rotating the H shape by 90° may be alternately repeatedly arranged in the first direction (e.g., x direction or −x direction) and the second direction (e.g., y direction or −y direction). Two opposite ends of each first bridge portion 12 are respectively connected to first island portions 11 next (adjacent) to each other, and one side of each first bridge portion 12 may be spaced apart from one side of a neighboring (adjacent) first island portion 11 and/or one side of another first bridge portion 12 by the first opening CS1.

The display device 1 may include second island portions 21 apart from each other, and second bridge portions 22 extending to second island portions 21 next (adjacent) to each other in the non-display area, e.g., the first non-display area NDA1 shown in FIG. 4A.

Each second island portion 21 may extend in the first direction (e.g., x direction or −x direction). The second island portions 21 may be spaced apart from each other in the second direction (e.g., the y direction or the −y direction) crossing the first direction (e.g., x direction or −x direction). Each second island portion 21 may include drivers of the gate driving circuit GDC (FIG. 3) described with reference to FIG. 3.

The second bridge portion 22 may have a serpentine shape. The length of the second bridge portion 22 may be greater than the shortest distance between second island portions 21 next (adjacent) to each other in the second directions (e.g., y direction or −y direction). In an embodiment, the second bridge portion 22 may have an approximate omega (Ω) shape convex toward the first direction (e.g., x direction or −x direction). The second bridge portions 22 may be disposed between second island portions 21 next (adjacent) to each other and be spaced apart from each other.

The second bridge portions 22 between second island portions 21 next (adjacent) to each other may be spaced apart from each other by a second opening CS2. Between next (adjacent) second island portions 21, the second openings CS2 and the second bridge portions 22 may be alternately arranged in the first direction (e.g., x direction or −x direction). The second openings CS2 may have the same shape. Two opposite ends of each second bridge portion 22 respectively extend to second island portions 21 next (adjacent) to each other, and one side of each second bridge portion 22 may be spaced apart from one side of a neighboring (adjacent) second island portion 21 and/or one side of another second bridge portion 22 by the second opening CS2.

One of the second island portions 21 disposed in the first non-display area NDA1 may correspond to first island portions 11 in a plurality of rows arranged in the display area DA. In an embodiment, one of the second island portions 21 disposed in the first non-display area NDA1 may correspond to first island portions 11 arranged in an i-th row in the display area DA, and first island portions 11 arranged in an (i+1)-th row in the display area DA (here, i is a positive integer greater than 0). Although it is shown in FIG. 4A that the second island portion 21 corresponds to two rows of the first island portions 11, the disclosure is not limited thereto. In another embodiment, one of second island portions 21 disposed in the first non-display area NDA1 may correspond to n rows of the first island portions 11 disposed in the display area DA (here, i is a positive integer equal to or greater than 3).

The non-display area, e.g., the first non-display area NDA1 may include a first sub-non-display area SNDA1 in which the second island portions 21 and the second bridge portions 22 are disposed, and a second sub-non-display area SNDA2 between the first sub-non-display area SNDA1 and the display area DA. Third bridge portions 23 may be disposed in the second sub-non-display area SNDA2, where the third bridge portions 23 extending to the display area DA and the first sub-non-display area SNDA1. One end of the third bridge portion 23 may be extended to the second island portion 21 and/or the second bridge portion 22, and an opposite end of the third bridge portion 23 may be extended to the first island portion 11 and/or the first bridge portion 12.

The third bridge portion 23 may have a serpentine shape. In an embodiment, the shape of the third bridge portion 23 may be different from the shape of each of the first bridge portion 12 and the second bridge portion 22. In an embodiment, as shown in FIG. 4A, the third bridge portion 23 may have an approximate omega (Ω) shape convex toward the second direction (e.g., y direction or −y direction). The third bridge portions 23 may have a symmetrical structure in which one of neighboring (adjacent) third bridge portions 23 arranged in the second direction (e.g., y direction or −y direction) may be convex in y direction and another may be convex in −y direction. Between the third bridge portions 23, a structure in which a third opening CS3 and a fourth opening CS4 having different shapes are repeated may be provided. The width of the third bridge portion 23 may be different from the width of the first bridge portion 12 and the width of the second bridge portion 22. In an embodiment, the width of the third bridge portion 23 may be greater than the width of the first bridge portion 12 and less than the width of the second bridge portion 22.

It is shown in FIG. 4A that the second island portion 21 and second bridge portion 22 in the non-display area, e.g., the first non-display area NDA1, respectively have shapes different from the shapes of the first island portion 11 and the first bridge portion 12 in the display area DA. In another embodiment, the second island portion 21 and second bridge portion 22 in the non-display area may respectively have the same shape as that of the shape of the first island portion 11 and the first bridge portion 12 in the display area DA.

FIG. 4B is an enlarged plan view of an embodiment of a portion of the display device 1, showing a region IV of FIG. 3 according to the disclosure.

Referring to FIG. 4B, the display device 1 includes the first island portions 11 apart from each other, and the first bridge portions 12 apart from each other by the first opening CS1 and connecting first island portions 11 next (adjacent) to each other in the display area DA. The structure of the display area DA in FIG. 4B may be the same as the structure of the display area DA described above with reference to FIG. 4A.

The display device 1 may include the second island portions 21 and second bridge portions 22 disposed in the non-display area, e.g., the first non-display area NDA1. In an embodiment, the second island portions 21 and the second bridge portions 22 may respectively have the same shapes as the shapes of the first island portions 11 and the first bridge portions 12.

The second island portions 21 may be spaced apart from each other in the first direction (e.g., x direction or −x direction) and the second direction (e.g., y direction or −y direction) in the non-display area, e.g., the first non-display area NDA1. Each of the second bridge portions 22 may connect second island portions 21 next (adjacent) to each other. The second bridge portions 22 may be spaced apart from each other by a second opening CS2 defined between the second bridge portions 22.

The second opening CS2 may have substantially the same shape as that of the shape of the first opening CS1. In an embodiment, the second opening CS2 having an approximate H shape and the second opening CS2 having an approximate I shape may be alternately repeatedly arranged in the non-display area, e.g., the first non-display area NDA1. Two opposite ends of each second bridge portion 22 are respectively connected to second island portions 21 next (adjacent) to each other, and one side of each second bridge portion 22 may be spaced apart from one side of a neighboring (adjacent) second island portion 21 and/or one side of another second bridge portion 22 by the second opening CS2.

Each second island portion 21 may be connected to four second bridge portions 22. Each second island portion 21 may include drivers of the gate driving circuit GDC (FIG. 2) described with reference to FIG. 3.

The second island portions 21 in one of rows disposed in the first non-display area NDA1 may correspond to first island portions 11 in one of rows arranged in the display area DA. In an embodiment, the second island portions 21 arranged in an i-th row in the first direction (e.g., x direction or −x direction) in the first non-display area NDA1 may correspond to the first island portions 11 arranged in the same row, e.g., the i-th row in the display area DA (here, i is a positive integer greater than 0).

The display device 1 may include the third bridge portions 23 disposed in the second sub-non-display area SNDA2 connecting the display area DA to the first sub-non-display area SNDA1. The non-display area, e.g., the first non-display area NDA1 may include the first sub-non-display area SNDA1 in which the second island portions 21 and the second bridge portions 22 are disposed, and the second sub-non-display area SNDA2 including the third bridge portions 23 and disposed between the first sub-non-display area SNDA1 and the display area DA. The third bridge portion 23 may be substantially the same as the first bridge portion 12 and the second bridge portion 22. In an embodiment, the width of the third bridge portion 23 may be the same as the width of the first bridge portion 12 and the width of the second bridge portion 22.

FIG. 4C is an enlarged plan view of an embodiment of a portion of the display device, showing a region IV of FIG. 3 according to the disclosure.

Referring to FIG. 4C, the display device 1 may include first island portions 11 and first bridge portions 12 extended to first island portions 11 next (adjacent) to each other, where the first island portions 11 are spaced apart from each other in the first direction (e.g., x direction or −x direction) and the second direction (e.g., y direction or −y direction) in the display area DA.

The first bridge portions 12 may be spaced apart from each other by a first opening CS1 defined between the first bridge portions 12. The first bridge portion 12 may have a serpentine shape. In an embodiment, as shown in FIG. 4C, the first bridge portion 12 may have a shape of an approximate ‘letter S’ such as including two rounded portions 12R and a straight portion 12S between the two rounded portions 12R.

Each first island portion 11 may be extended to a plurality of first bridge portions 12. In an embodiment, each first island portion 11 may be extended to four first bridge portions 12. Two first bridge portions 12 may be disposed on two opposite sides of the first island portion 11 in the first direction (e.g., x direction or −x direction), and the remaining two first bridge portions 12 may be disposed on two opposite sides of the first island portion 11 in the second direction (e.g., y direction or −y direction). Four first bridge portions 12 may be respectively extended to four sides of the first island portion 11. Four first bridge portions 12 may be respectively next (adjacent) to the corners of the first island portion 11.

In the non-display area, e.g., the first non-display area NDA1 shown in FIG. 4C, the display device 1 may include the second island portions 21 apart from each other in the first direction (e.g., x direction or −x direction) and the second direction (e.g., y direction or −y direction), and the second bridge portions 22 extended to second island portions 21 next (adjacent) to each other.

The second bridge portions 22 may be spaced apart from each other by a second opening CS2 defined between the second bridge portions 22. The second bridge portion 22 may have a serpentine shape. In an embodiment, as shown in FIG. 4C, the second bridge portion 22 may have an approximate ‘alphabet S’ shape. The size and/or width of the second bridge portion 22 may be different from the size and/or width of the first bridge portion 12. In an embodiment, the size and/or width of the second bridge portion 22 may be greater than the size and/or width of the first bridge portion 12. The radius of curvature of a rounded portion of the second bridge portion 22 may be different from the radius of curvature of a rounded portion of the first bridge portion 12. In an embodiment, the radius of curvature of a rounded portion of the second bridge portion 22 may be greater than the radius of curvature of a rounded portion of the first bridge portion 12.

Each second island portion 21 may be extended to a plurality of second bridge portions 22. Each second island portion 21 may be extended to four second bridge portions 22. Two second bridge portions 12 may be disposed on two opposite sides of the second island portion 21 in the first direction (e.g., x direction or −x direction), and the remaining two second bridge portions 22 may be disposed on two opposite sides of the second island portion 21 in the second direction (e.g., y direction or −y direction). In an embodiment, four second bridge portions 22 may be respectively extended to four sides of the second island portion 21. Each second bridge portion 22 may be extended to the central portion of each side of the second island portion 21.

The second island portions 21 in one of rows disposed in the first non-display area NDA1 may correspond to the first island portions 11 in a plurality of rows arranged in the display area DA. In an embodiment, the second island portions 21 in one of rows disposed in the first non-display area NDA1 may correspond to first island portions 11 arranged in an i-th row in the display area DA, and first island portions 11 arranged in an (i+1)-th row in the display area DA (here, i is a positive integer greater than 0). In another embodiment, the second island portions 21 in one of rows may correspond to n rows of first island portions 11 (here, n is a positive integer equal to or greater than 3).

The non-display area, e.g., the first non-display area NDA1 may include a first sub-non-display area SNDA1 in which the second island portions 21 and the second bridge portions 22 are disposed, and a second sub-non-display area SNDA2 between the first sub-non-display area SNDA1 and the display area DA. Third bridge portions 23 may be disposed in the second sub-non-display area SNDA2, where the third bridge portions 23 extended to the display area DA and the first sub-non-display area SNDA1. One end of the third bridge portion 23 may be extended to the second island portion 21, and an opposite end of the third bridge portion 23 may be extended to the first island portion 11. In an embodiment, one end of the third bridge portion 23 may be extended to the central portion of one side of the second island portion 21, and an opposite end of the third bridge portion 23 may be extended to the central portion of one side of the first island portion 11.

The third bridge portion 23 may have a serpentine shape. In an embodiment, the shape of the third bridge portion 23 may be different from the shape of each of the first bridge portion 12 and the second bridge portion 22. The width of the third bridge portion 23 may be different from the width of the first bridge portion 12 and the width of the second bridge portion 22. The width of the third bridge portion 23 may be greater than the width of the first bridge portion 12 and less than the width of the second bridge portion 22. Between the third bridge portions 23 in the second direction (e.g., y direction or −y direction), the third opening CS3 and the fourth opening CS4 having different shapes may be alternately disposed.

FIG. 4D is an enlarged plan view of an embodiment of a portion of the display device 1, showing the display area DA of FIG. 3 according to the disclosure.

Referring to FIG. 4D, the display device 1 may include first island portions 11 and first bridge portions 12 extended to first island portions 11 next (adjacent) to each other, where the first island portions 11 are spaced apart from each other in the first direction (e.g., x direction or −x direction) and the second direction (e.g., y direction or −y direction) in the display area DA. The first bridge portions 12 may be spaced apart from each other by a first opening CS1 defined between the first bridge portions 12.

In an embodiment, at least one of sides of the island portion 11 may be oblique with respect to an imaginary line extended to centers C of the island portions 11 in the first direction (e.g., x direction or −x direction) and/or the second direction (e.g., y direction or −y direction). With regard to this, it is shown in FIG. 4D that the first island portion 11 includes first to fourth sides 11a, 11b, 11c, and 11d, and the first to fourth sides 11a, 11b, 11c, and 11d extend in a direction oblique with respect to a first imaginary line IM1 extended to the centers C of the island portions 11. Although it is shown in FIG. 4D that the first imaginary line IM1 extends in the first direction (e.g., x direction or −x direction), the first imaginary line IM1 may extend in the second direction (e.g., y direction or −y direction).

In an embodiment, the first side 11a and the third side 11c parallel to each other may cross the first imaginary line IM1. A relatively small angle φ (hereinafter, also referred to as an minor angle) among angles formed by the first side 11a and the first imaginary line IM1 may be greater than 0° and less than 90°. The minor angle φ between the third side 11c and the first imaginary line IM1 may be greater than 0° and less than 90°.

The first island portion 11 may be extended to a plurality of first bridge portions 12. In an embodiment, the first island portion 11 may be extended to four first bridge portions 12. Two first bridge portions 12 may be disposed on two opposite sides of the first island portion 11 in the first direction (e.g., x direction or −x direction), and the remaining two first bridge portions 12 may be disposed on two opposite sides of the first island portion 11 in the second direction (e.g., y direction or −y direction).

The first bridge portion 12 may have a serpentine shape. In an embodiment, as shown in FIG. 4D, the first bridge portion 12 may have a shape of an approximate ‘alphabet S’ such as including two rounded portions 12R and a straight portion 12S between the two rounded portions 12R.

In an embodiment, as shown in FIG. 4D, the straight portion 12S may be substantially parallel to a side of a neighboring (adjacent) first island portion 11. In an embodiment, the straight portion 12S of each of the first bridge portions 12 disposed on two opposite sides of the first island portion 11 in the first direction (e.g., x direction or −x direction) may be substantially parallel to a side (e.g., the first side 11a and the third side 11c) of the first island portion 11. The straight portion 12S of each of the first bridge portions 12 disposed on two opposite sides of the first island portion 11 in the second direction (e.g., y direction or −y direction) may be substantially parallel to a side (e.g., the second side 11b and the fourth side 11d) of the first island portion 11.

Each of the first island portions 11 shown in FIG. 4D may be understood as each of the first island portions 11 shown in FIG. 4C being rotated by a first angle (e.g., an acute angle) with respect to the center C. Accordingly, at least one of sides of the island portion 11 may be oblique with respect to an imaginary line extended to centers C of the island portions 11 in the first direction (e.g., x direction or −x direction) and/or the second direction (e.g., y direction or −y direction). Depending on the arrangement of the first island portions 11 and/or the structure of the first bridge portion 12, the area of the first opening CS1 shown in FIG. 4D may be relatively less than the area of the first opening CS1 shown in FIG. 4C, and accordingly, the display device 1 in the embodiment shown in FIG. 4D may provide relatively high-resolution images.

Although it is shown in FIG. 4D that the straight portion 12S of the first bridge portion 12 is substantially parallel to a side of a first island portion 11 next (adjacent) to the straight portion 12S, the disclosure is not limited thereto. In another embodiment, the straight portion 12S of the first bridge portion 12 may be oblique to a side of a first island portion 11 next (adjacent) to the straight portion 12S as shown in FIG. 4C.

In an embodiment, the structure of the first non-display area NDA1 (FIG. 3) of the display device 1 not disclosed in FIG. 4D may be the same as the structure of the display area DA disclosed in FIG. 4D. In an embodiment, the structure of the first non-display area NDA1 (FIG. 3) of the display device 1 not disclosed in FIG. 4D may be substantially the same as the structure of the display area DA disclosed in FIG. 4D, and the area of the second island portion disposed in the first non-display area NDA1 (FIG. 3) may be greater than the area of the first island portion 11. In this case, one second island portion may correspond to the plurality of first island portions 11 arranged in rows next (adjacent) to each other as described with reference to FIG. 4C. In an embodiment, the structure of the first non-display area NDA1 (FIG. 3) of the display device 1 not disclosed in FIG. 4D may be substantially the same as the structure of the first non-display area NDA1 shown in one of FIGS. 4A to 4C. The structure of the first non-display area NDA1 may be variously selected in the scope disclosed in the specification.

FIG. 4E is an enlarged plan view of an embodiment of a portion of the display device, showing a region IV of FIG. 3 according to the disclosure.

Referring to FIG. 4E, the display device 1 includes the first island portions 11 apart from each other in the display area DA, and the first bridge portions 12 apart from each other by the first opening CS1 and extended to first island portions 11 next (adjacent) to each other.

The first opening CS1 may have a bar shape. The first opening CS1 may have a first sub-opening CS1A extending in the first direction (x direction or −x direction) and a second sub-opening CS1B extending in the second direction (y direction or −y direction). Each of the first sub-opening CS1A and the second sub-opening CS1B may have a bar shape. The first sub-opening CS1A and the second sub-opening CS1B may have substantially the same width and length. The length of each of the first sub-opening CS1A and the second sub-opening CS1B represents a value measured in an extension direction, and the width represents a value measured in a direction perpendicular to the length direction (e.g., extension direction).

The display device 1 may include the second island portions 21 and the second bridge portions 22 disposed in the non-display area, e.g., the first sub-non-display area SNDA1. The second island portions 21 may be spaced apart from each other in the first direction (e.g., x direction or −x direction) and the second direction (e.g., y direction or −y direction) in the first sub-non-display area SNDA1. Each of the second bridge portions 22 may be extended to second island portions 21 next (adjacent) to each other. The second bridge portions 22 may be spaced apart from each other by a second opening CS2 defined between the second bridge portions 22.

The second opening CS2 may have a bar shape. The second opening CS2 may have a first sub-opening CS2A extending in the first direction (x direction or −x direction) and a second sub-opening CS2B extending in the second direction (y direction or −y direction). Each of the first sub-opening CS2A and the second sub-opening CS2B may have a bar shape. The first sub-opening CS2A and the second sub-opening CS2B may have substantially the same width and length. Each second island portion 21 may be extended to four second bridge portions 22. Each second island portion 21 may include drivers of the gate driving circuit GDC (FIG. 2) described with reference to FIG. 3. Some of the drivers of the gate driving circuit GDC may be disposed in also the second sub-non-display area SNDA2. In an embodiment, some of third island portions 31 may include some of drivers.

One of the second island portions 21 disposed in the first non-display area NDA1 may correspond to first island portions 11 in a plurality of rows arranged in the display area DA. In an embodiment, one of the second island portions 21 disposed in the first non-display area NDA1 may correspond to first island portions 11 arranged in an i-th row in the display area DA, and first island portions 11 arranged in an (i+1)-th row in the display area DA (here, i is a positive integer greater than 0). Although it is shown in FIG. 4E that the second island portion 21 corresponds to two rows of the first island portions 11, the disclosure is not limited thereto. In another embodiment, one of second island portions 21 disposed in the first non-display area NDA1 may correspond to n rows of the first island portions 11 disposed in the display area DA (here, i is a positive integer equal to or greater than 3).

The display device 1 may include the third island portions 31 and third bridge portions 32 disposed in the second sub-non-display area SNDA2 extended to the display area DA and the first sub-non-display area SNDA1. Third island portions 31 next (adjacent) to each other may be spaced apart from each other by the third opening CS3 and be extended by the third bridge portions 32.

The third opening CS3 may have a bar shape. The third opening CS3 may have a first sub-opening CS3A extending in the first direction (x direction or −x direction) and a second sub-opening CS3B extending in the second direction (y direction or −y direction). Each of the first sub-opening CS3A and the second sub-opening CS3B may have a bar shape. The first sub-opening CS3A and the second sub-opening CS3B may have different widths and/or lengths from each other.

In an embodiment, a length of the first sub-opening CS3A of the third opening CS3 in the first direction (x direction or −x direction) may be equal to or greater than a length of the second sub-opening CS3B of the third opening CS3 in the second direction (y direction or −y direction). A width of the first sub-opening CS3A of the third opening CS3 in the second direction (y direction or −y direction) may be less than a width of the second sub-opening CS3B of the third opening CS3 in the first direction (x direction or −x direction).

In an embodiment, a length of the first sub-opening CS3A of the third opening CS3 in the first direction (x direction or −x direction) may be equal to a length of the first sub-opening CS2A of the second opening CS2 in the first direction (x direction or −x direction), and greater than a length of the first sub-opening CS1A of the first opening CS1 in the first direction (x direction or −x direction). A width of the first sub-opening CS3A of the third opening CS3 in the second direction (y direction or −y direction) may be less than a length of the first sub-opening CS2A of the second opening CS2 in the second direction (y direction or −y direction), and greater than a width of the first sub-opening CS1A of the first opening CS1 in the second direction (y direction or −y direction).

In an embodiment, a length of the second sub-opening CS3B of the third opening CS3 in the second direction (y direction or −y direction) may be equal to a length of the second sub-opening CS2B of the second opening CS2 in the second direction (y direction or −y direction), and greater than a length of the second sub-opening CS1B of the first opening CS1 in the second direction (y direction or −y direction). A width of the second sub-opening CS3B of the third opening CS3 in the first direction (x direction or −x direction) may be equal to a length of the second sub-opening CS2B of the second opening CS2 in the first direction (x direction or −x direction), and greater than a width of the second sub-opening CS1B of the first opening CS1 in the first direction (x direction or −x direction).

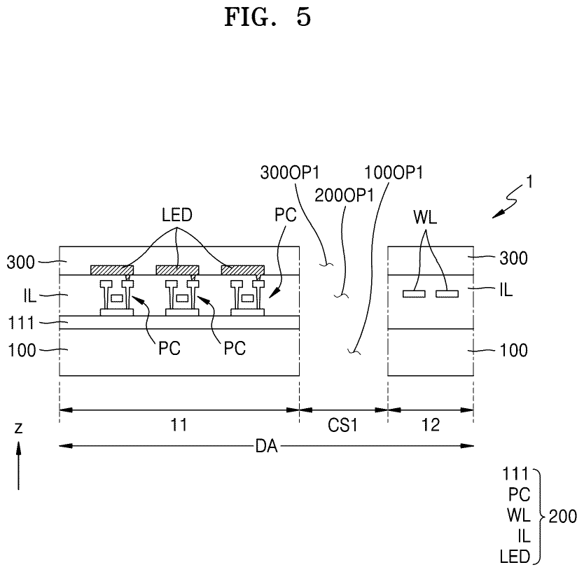

FIG. 5 is a schematic cross-sectional view of an embodiment of the first island portion 11 and the first bridge portion 12 disposed in the display area DA of the display device 1 according to the disclosure.

Referring to FIG. 5, the first island portion 11 and the first bridge portion 12 disposed in the display area DA may be spaced apart from each other with the first opening CS1 therebetween. The first island portion 11 may include light-emitting elements LED and a circuit electrically connected thereto and driving the light-emitting element LED, e.g., a pixel driving circuit PC, and the first bridge portions 12 may include a wiring WL electrically connected to the pixel driving circuits PC disposed in each of first island portions 11 next (adjacent) to each other.

In the first island portion 11, a buffer layer 111 including an inorganic insulating material may be disposed on the substrate 100, and the pixel driving circuit PC may be disposed on the buffer layer 111. An insulating layer IL including an inorganic insulating material and/or an organic insulating material may be disposed between the pixel driving circuit PC and the light-emitting element LED. The light-emitting element LED may be disposed on the insulating layer IL and electrically connected to the pixel driving circuit PC corresponding thereto. The light-emitting elements LED may emit light of different colors or light of the same color. In an embodiment, the light-emitting elements LED may emit red, green, and blue light. In an embodiment, the light-emitting elements LED may emit white light. In another embodiment, the light-emitting elements LED may emit red, green, blue light, and white light.

The substrate 100 may include polymer resin such as polyethersulfone, polyarylate, polyetherimide, polyethylene naphthalate, polyethylene terephthalate, polyphenylene sulfide, polyimide, polycarbonate, cellulose tri acetate, cellulose acetate propionate, or the like. In an embodiment, the substrate 100 may be a single layer including the polymer resin. In another embodiment, the substrate 100 may have a multi-layered structure including a base layer and a barrier layer, where the base layer includes the above polymer resin and the barrier layer includes an inorganic insulating material.

In an embodiment, although it is shown in FIG. 5 that three pixel driving circuits PC are disposed in each first island portion 11, and three light-emitting elements LED are respectively connected to the pixel driving circuits PC, the disclosure is not limited thereto. In another embodiment, the number of pixel driving circuits PC and the number of light-emitting elements LED disposed in the first island portion 11 may be one, two, or four or more.

An encapsulation layer 300 may be disposed on the light-emitting element LED and may protect the light-emitting element LED from external force and/or moisture transmission. The encapsulation layer 300 may include an inorganic encapsulation layer and/or an organic encapsulation layer. In an embodiment, the encapsulation layer 300 may include a structure in which an inorganic encapsulation layer including an inorganic insulating material, an organic encapsulation layer including an organic insulating material, and an inorganic encapsulation layer including an inorganic insulating material are stacked. In another embodiment, the encapsulation layer 300 may include an organic material such as resin. In an embodiment, the encapsulation layer 300 may include urethane epoxy acrylate. The encapsulation layer 300 may include a photosensitive material, e.g., a material such as photoresist.

In the first bridge portion 12, the insulating layer IL including an organic insulating material may be disposed on the substrate 100. When the display device 1 is stretched, the first bridge portion 12, which is relatively subject to a relatively large amount of transformation, may not have a layer including an inorganic insulating material that is prone to cracking, unlike the first island portion 11.

In an embodiment, the substrate 100 corresponding to the first bridge portion 12 may have the same stack structure as a stack structure of the substrate 100 corresponding to the first island portion 11. In an embodiment, the substrate 100 corresponding to the first bridge portion 12 and the substrate 100 corresponding to the first island portion 11 may be polymer resin layers simultaneously formed during the same process. In another embodiment, the substrate 100 corresponding to the first bridge portion 12 may have a different stack structure from a stack structure of the substrate 100 corresponding to the first island portion 11. In an embodiment, the substrate 100 corresponding to the first bridge portion 12 may have a multi-layered structure including a base layer that includes a polymer resin and a barrier layer that includes an inorganic insulating material, and the substrate 100 corresponding to the first bridge portion 12 may have a structure of a polymer resin layer in which a layer including an inorganic insulating material is absent.

As described above, the wirings WL of the first bridge portion 12 may be signal lines (e.g., a gate line, a data line, or the like) for providing electrical signals, or voltage lines (e.g., a driving voltage line, an initialization voltage line, or the like) for providing voltages to transistors included in the pixel driving circuit PC of the first island portion 11. The encapsulation layer 300 may be disposed on also the first bridge portion 12. In another embodiment, the encapsulation layer 300 may not be present in the first bridge portion 12.

Referring to FIGS. 4A to 4E, and 5, the substrate 100 corresponding to the first island portion 11 and the substrate 100 corresponding to the first bridge portion 12 may be connected to each other. In other words, the plan views shown in FIGS. 4A to 4E may be substantially the same as the plan view of the substrate 100 in FIG. 5. In other words, the substrate 100 may include a region corresponding to the first island portion 11, and a region corresponding to the first bridge portion 12, and an opening 100OP1 having the same shape as a shape of the first opening CS1 may be defined in the substrate 100.

Similarly, the encapsulation layer 300 corresponding to the first island portion 11 and the encapsulation layer 300 corresponding to the first bridge portion 12 may be connected to each other. In an embodiment, the plan views shown in FIGS. 4A to 4E may be substantially the same as the plan view of the encapsulation layer 300. In other words, the encapsulation layer 300 may include a region corresponding to the first island portion 11, a region corresponding to the first bridge portion 12, and an opening 300OP1 having the same shape as a shape of the first opening CS1.

A circuit-light-emitting element layer 200 between the substrate 100 and the encapsulation layer 300 may include the buffer layer 111, the pixel driving circuit PC, the wiring WL, the insulating layer IL, and the light-emitting element LED. Similar to the substrate 100, the plan views shown in FIGS. 4A to 4E may be substantially the same as the plan view of the circuit-light-emitting element layer 200. In other words, the circuit-light-emitting element layer 200 may define an opening 200OP1 having the same shape as a shape of the first opening CS1.

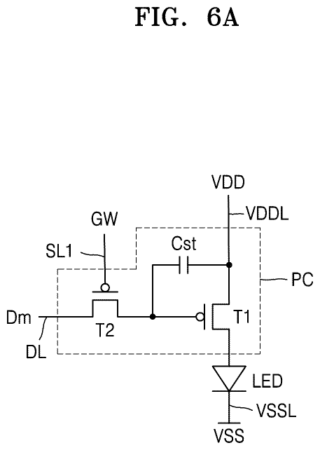

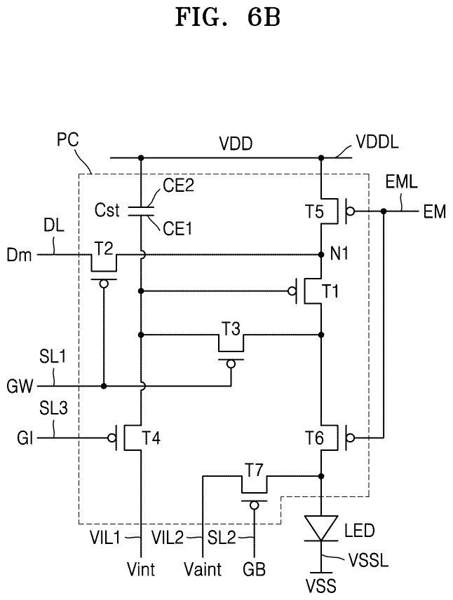

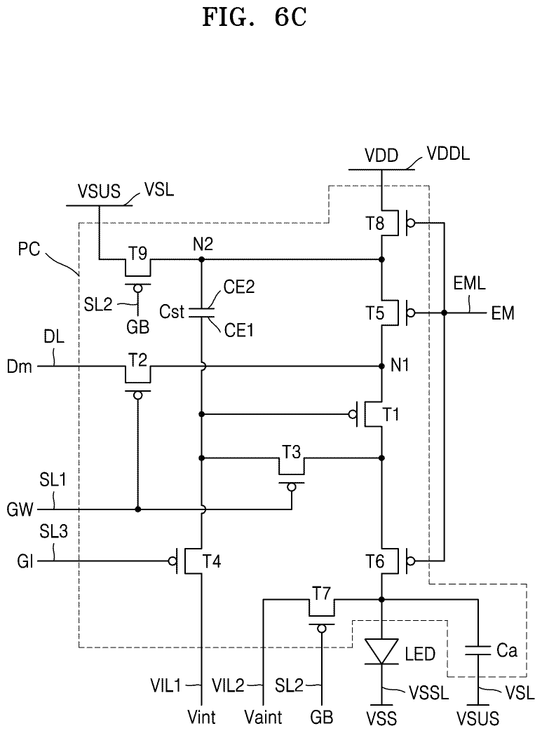

FIGS. 6A to 6C are equivalent circuit diagrams of an embodiment of a sub-pixel of the display device 1 according to the disclosure.

Referring to FIG. 6A, the light-emitting element LED corresponding to a sub-pixel may be electrically connected to the pixel driving circuit PC, and the pixel driving circuit PC may include a first transistor T1, a second transistor T2, and a storage capacitor Cst. The pixel driving circuit PC may be electrically connected to a signal line and a voltage line. The signal line may include a gate line such as a first scan line SL1, and a data line DL, and the voltage line may include a first voltage line VDDL.

The second transistor T2 may be electrically connected to the first scan line SL1 and the data line DL. The first scan line SL1 may provide a first scan signal GW to a gate electrode of the second transistor T2. The second transistor T2 may transfer a data signal Dm to the first transistor T1 according to a first scan signal GW input from the first scan line GL1, where the data signal Dm is input from the data line DL.

The storage capacitor Cst may be electrically connected to the second transistor T2 and the first voltage line VDDL and may store a voltage corresponding to a difference between a voltage transferred from the second transistor T2 and a first power voltage VDD supplied by the first voltage line VDDL.

The first transistor T1 is a driving transistor and may control a driving current flowing through the light-emitting element LED. The first transistor T1 may be connected to the first voltage line VDDL and the storage capacitor Cst. The first transistor T1 may control the driving current flowing from the first voltage line VDDL to the light-emitting element LED in response to a voltage value stored in the storage capacitor Cst. The light-emitting element LED may emit light having a preset brightness based on the driving current. A first electrode of the light-emitting element LED may be electrically connected to the first transistor T1, and a second electrode may be electrically connected to a second voltage line VSSL supplying a second power voltage VSS.

Although it is shown in FIG. 6A that the pixel driving circuit PC includes two transistors and one storage capacitor, the pixel driving circuit PC may include three or more transistors in another embodiment.

Referring to FIG. 6B, the pixel driving circuit PC may include the first transistor T1, the second transistor T2, a third transistor T3, a fourth transistor T4, a fifth transistor T5, a sixth transistor T6, a seventh transistor T7, and the storage capacitor Cst.

The pixel driving circuit PC is electrically connected to signal lines and voltage lines. The signal lines may include a gate line such as the first scan line SL1, a second scan line SL2, a third scan line SL3, and an emission control line EML, and the data line DL. The voltage lines may include first and second initialization voltage lines VIL1 and VIL2, and the first voltage line VDDL.

The first voltage line VDDL may transfer the first power voltage VDD to the first transistor T1. The first initialization voltage line VIL1 may transfer a first initialization voltage Vint to the pixel driving circuit PC, where the first initialization voltage Vint initializes the first transistor T1. The second initialization voltage line VIL2 may transfer a second initialization voltage Vaint to the pixel driving circuit PC, where the second initialization voltage Vaint initializes the first electrode of the light-emitting element LED.

The first transistor T1 may be connected to the first voltage line VDDL through the fifth transistor T5 and electrically connected to the light-emitting element LED through the sixth transistor T6. The first transistor T1 serves as a driving transistor, and receives a data signal Dm and supplies the driving current to the light-emitting element LED according to a switching operation of the second transistor T2.

The second transistor T2 is a data-write transistor and is electrically connected to the first scan line SL1 and the data line DL. The second transistor T2 is electrically connected to the first voltage line VDDL through the fifth transistor T5. The second transistor T2 is turned on according to a first scan signal GW transferred through the first scan line SL1, and performs a switching operation of transferring a data signal Dm to a first node N1, the data signal Dm being transferred through the data line DL.

The third transistor T3 is electrically connected to the first scan line SL1 and electrically connected to the light-emitting element LED through the sixth transistor T6. The third transistor T3 may be turned on according to a first scan signal GW to diode-connect the first transistor T1, where the first scan signal GW is transferred through the first scan line SL1.

The fourth transistor T4 is a first initialization transistor and is electrically connected to the third scan line SL3 and the first initialization voltage line VIL1. The fourth transistor T4 may be turned on according to a third scan signal GI to initialize a voltage of the gate electrode of the first transistor T1 by transferring the first initialization voltage Vint to the gate electrode of the first transistor T1, where the first initialization voltage Vint is from the first initialization voltage line VIL1, and the third scan signal GI is transferred through the third scan line SL3. The third scan signal GI may correspond to a first scan signal of another pixel driving circuit disposed in a previous row of the relevant pixel driving circuit PC.

The fifth transistor T5 may be an operation control transistor, and the sixth transistor T6 may be an emission control transistor. The fifth transistor T5 and the sixth transistor T6 may be electrically connected to the emission control line EML, simultaneously turned on according to an emission control signal EM transferred through the emission control line EML, and may form a current path such that the driving current flows in a direction from the first voltage line VDDL to the light-emitting element LED.

The seventh transistor T7 is a second initialization transistor and may be electrically connected to the second scan line SL2, the second initialization voltage line VIL2, and the sixth transistor T6. The seventh transistor T7 is turned on according to a second scan signal GB transferred through the second scan line SL2, and may transfer the second initialization voltage Vaint from the second initialization voltage line VIL2 to the first electrode of the light-emitting element LED, thereby initializing the first electrode of the light-emitting element LED.

The storage capacitor Cst includes a first electrode CE1 and a second electrode CE2. The first electrode CE1 is electrically connected to the gate electrode of the first transistor T1, and the second electrode CE2 is electrically connected to the first voltage line VDDL. The storage capacitor Cst may maintain a voltage applied to the gate electrode of the first transistor T1 by storing and maintaining a voltage corresponding to a difference between voltages of two opposite ends of the gate electrode of the first transistor T1 and the first voltage line VDDL.

Referring to FIG. 6C, the pixel driving circuit PC may include the first transistor T1, the second transistor T2, the third transistor T3, the fourth transistor T4, the fifth transistor T5, the sixth transistor T6, the seventh transistor T7, an eighth transistor T8, a ninth transistor T9, the storage capacitor Cst, and an auxiliary capacitor Ca.

The pixel driving circuit PC is electrically connected to signal lines and voltage lines. The signal lines may include a gate line such as the first scan line SL1, the second scan line SL2, the third scan line SL3, and the emission control line EML, and the data line DL. The voltage lines may include the first and second initialization voltage lines VIL1 and VIL2, a sustain voltage line VSL, and the first voltage line VDDL.

The first voltage line VDDL may transfer the first power voltage VDD to the first transistor T1. The first initialization voltage line VIL1 may transfer the first initialization voltage Vint to the pixel driving circuit PC, where the first initialization voltage Vint initializes the first transistor T1. The second initialization voltage line VIL2 may transfer the second initialization voltage Vaint to the pixel driving circuit PC, where the second initialization voltage Vaint initializes the first electrode of the light-emitting element LED. The sustain voltage line VSL may provide a sustain voltage VSUS to a second node N2, e.g., the second electrode CE2 of the storage capacitor Cst during an initialization section and a data-write section.

The first transistor T1 may be electrically connected to the first voltage line VDDL through the fifth transistor T5 and the eighth transistor T8 and electrically connected to the light-emitting element LED through the sixth transistor T6. The first transistor T1 serves as a driving transistor, and may receive a data signal Dm and supply the driving current to the light-emitting element LED according to a switching operation of the second transistor T2.

The second transistor T2 is electrically connected to the first scan line SL1 and the data line DL and electrically connected to the first voltage line VDDL through the fifth transistor T5 and the eighth transistor T8. The second transistor T2 may be turned on according to a first scan signal GW transferred through the first scan line SL1 and may perform a switching operation of transferring a data signal Dm to the first node N1, where the data signal Dm is transferred through the data line DL.

The third transistor T3 is electrically connected to the first scan line SL1 and electrically connected to the light-emitting element LED through the sixth transistor T6. The third transistor T3 may be turned on according to a first scan signal GW to compensate for a threshold voltage of the first transistor T1 by diode-connecting the first transistor T1, where the first scan signal GW is transferred through the first scan line SL1.

The fourth transistor T4 is electrically connected to the third scan line SL3 and the first initialization voltage line VIL1, turned on according to a third scan signal GI transferred through the third scan line SL3, and initializes a voltage of the gate electrode of the first transistor T1 by transferring the first initialization voltage Vint from the first initialization voltage line VIL1 to the gate electrode of the first transistor T1. The third scan signal GI may correspond to a first scan signal of another pixel driving circuit disposed in a previous row of the relevant pixel driving circuit PC.

The fifth transistor T5, the sixth transistor T6, and the eighth transistor T8 may be electrically connected to the emission control line EML, simultaneously turned on according to an emission control signal EM transferred through the emission control line EML, and may form a current path such that the driving current flows in a direction from the first voltage line VDDL to the light-emitting element LED.

The seventh transistor T7 is a second initialization transistor and may be electrically connected to the second scan line SL2, the second initialization voltage line VIL2, and the sixth transistor T6. The seventh transistor T7 is turned on according to a second scan signal GB transferred through the second scan line SL2, and transfers the second initialization voltage Vaint from the second initialization voltage line VIL2 to the first electrode of the light-emitting element LED, thereby initializing the first electrode of the light-emitting element LED.

The ninth transistor T9 may be electrically connected to the second scan line SL2, the second electrode CE2 of the storage capacitor Cst, and the sustain voltage line VSL. The ninth transistor T9 is turned on according to a second scan signal GB transferred through the second scan line SL2 and may transfer the sustain voltage VSUS to the second node N2, e.g., the second electrode CE2 of the storage capacitor Cst during the initialization section and the data-write section.

Each of the eighth transistor T8 and the ninth transistor T9 may be electrically connected to the second node N2, e.g., the second electrode CE2 of the storage capacitor Cst. In an embodiment, during the initialization section and the data-write section, the eighth transistor T8 may be turned off and the ninth transistor T9 may be turned on. During an emission section, the eighth transistor T8 may be turned on and the ninth transistor T9 may be turned off. Because the sustain voltage VSUS is transferred to the second node N2 during the initialization section and the data-write section, uniformity (e.g., long range uniformity (“LRU”)) in brightness of the display device depending on a voltage drop of the first voltage line VDDL may be improved.

The storage capacitor Cst includes the first electrode CE1 and the second electrode CE2. The first electrode CE1 is electrically connected to the gate electrode of the first transistor T1, and the second electrode CE2 is electrically connected to the eighth transistor T8 and the ninth transistor T9.

The auxiliary capacitor Ca may be electrically connected to the sixth transistor T6, the sustain voltage line VSL, and the first electrode of the light-emitting element LED. The auxiliary capacitor Ca may prevent a black brightness from rising when the sixth transistor T6 is turned off by storing and maintaining a voltage corresponding to a voltage difference between the first electrode of the light-emitting element LED and the sustain voltage line VSL while the seventh transistor T7 and the ninth transistor T9 are turned on.

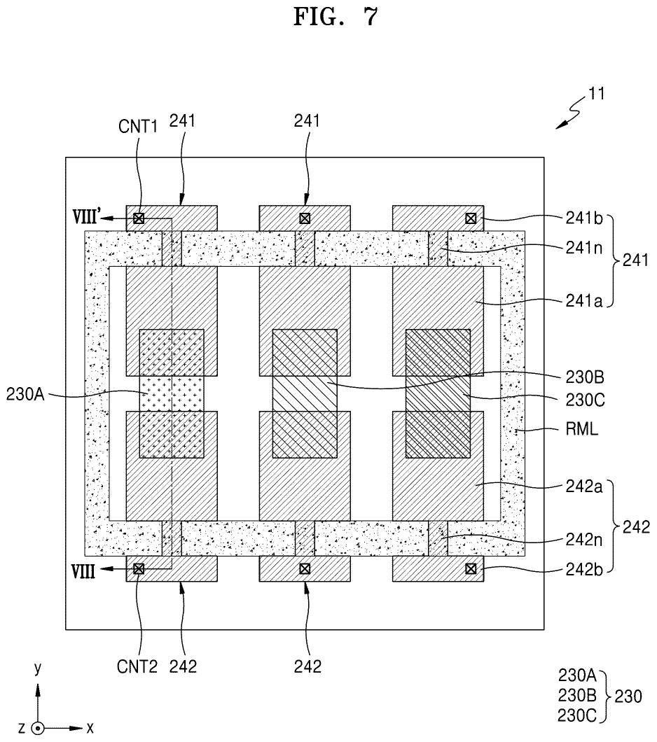

FIG. 7 is an excerpted plan view of an embodiment of a portion of the display area DA (FIG. 3) of the display device 1 according to the disclosure. FIG. 7 shows a planar structure of the first island portion 11 disposed in the display area DA (FIG. 3).

Referring to FIG. 7, the light-emitting elements may be disposed in the first island portion 11. In an embodiment, it is shown in FIG. 7 that first to third light-emitting elements (e.g., light-emitting diodes) 230A, 230B, and 230C emitting light of different colors are disposed in the first island portion 11. One of the first to third light-emitting elements 230A, 230B, and 230C may emit red light, another may emit green light, and the remaining one may emit blue light.

In an embodiment, although it is shown in FIG. 7 that three light-emitting elements 230 are disposed and three first electrode pads 241 respectively correspond to the light-emitting elements 230, the disclosure is not limited thereto. In another embodiment, two to four or more light-emitting elements 230 may be disposed and two or four or more first electrode pads 241 may be disposed in the first island portion 11. Hereinafter, for convenience of description, it is described that three light-emitting elements 230 are disposed in the first island portion 11.

Each of the light-emitting elements 230 may be electrically connected to the pixel driving circuit PC through the first electrode pad 241 (or first electrode layer). Each of the light-emitting elements 230 may be electrically connected to the second voltage line VSSL, which is a common voltage line, through a second electrode pad 242 (or second electrode layer).

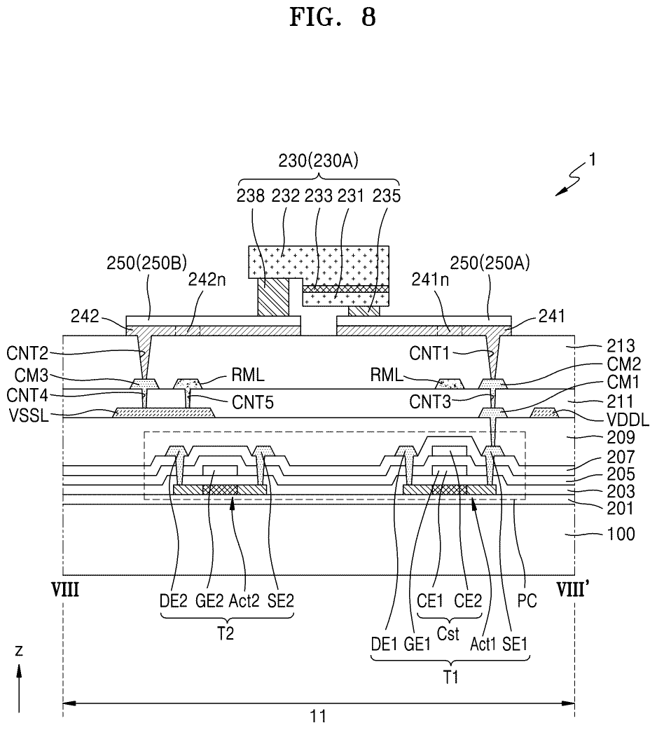

The first electrode pads 241 may be disposed apart from each other in one direction, e.g., the first direction (e.g., x direction or −x direction). Each of the first electrode pads 241 may be electrically connected to the relevant pixel driving circuit PC (FIG. 5, FIG. 8) through a first contact hole CNT1. The second electrode pads 242 may be disposed apart from each other in the first direction (e.g., x direction or −x direction) while being apart from the first electrode pads 241. Each of the second electrode pads 242 may be electrically connected to the relevant second voltage line VSSL (FIGS. 6A to 6C) through a second contact hole CNT2.

Each of the first electrode pads 241 may include a first portion 241a, a second portion 241b, and a portion 241n (hereinafter, connection portion), where the first portion 241a overlaps the light-emitting element 230, the second portion 241b is electrically connected to the pixel driving circuit PC (FIG. 5, FIG. 8) through the first contact hole CNT1, and the connection portion 241n is for connecting the first portion 241a to the second portion 241b. A width (e.g., width in the first direction) of the connection portion 241n may be less than a width (e.g., width in the first direction) of the first portion 241a and/or a width (e.g., width in the first direction) of the second portion 241b. The first portion 241a, the second portion 241b, and the connection portion 241n of the first electrode pad 241 may be connected to be a single body.

In an embodiment, each of the second electrode pads 242 may include a first portion 242a, a second portion 242b, and a connection portion 242n, where the first portion 242a overlaps the light-emitting element 230, the second portion 242b is electrically connected to the second voltage line VSSL (FIGS. 6A to 6C) through the second contact hole CNT2, and the connection portion 242n is for connecting the first portion 242a to the second portion 242b. A width (e.g., width in the first direction) of the connection portion 242n of the second electrode pad 242 may be less than a width (e.g., width in the first direction) of the first portion 242a and/or a width (e.g., width in the first direction) of the second portion 242b. The first portion 242a, the second portion 242b, and the connection portion 242n of the second electrode pad 242 may be connected to be a single body.

The first portion 241a of each of the first electrode pads 241 and the first portion 242a of each of the second electrode pads 242 may be spaced apart from each other and disposed next (adjacent) to each other. Each of the light-emitting elements 230 may overlap the first portion 241a of each of the first electrode pads 241 and the first portion 242a of each of the second electrode pads 242. The light-emitting elements 230 are respectively and electrically connected to the relevant first electrode pad 241 and second electrode pad 242.

A conductive pattern RML may overlap the first electrode pads 241. In an embodiment, the conductive pattern RML may overlap the connection portion 241n of each of the first electrode pads 241. In an embodiment, the conductive pattern RML may have a frame shape in a plan view. The conductive pattern RML may overlap the second electrode pads 242. The conductive pattern RML may overlap the connection portion 242n of each of the second electrode pads 242.

The conductive pattern RML may have a selected voltage level. In an embodiment, the conductive RML may have the same voltage level as the second electrode pad 242.

FIG. 8 is a cross-sectional view of an embodiment of a portion (e.g., the first island portion 11) of the display area DA of the display device 1, taken along line VIII-VIII′ of FIG. 7, according to the disclosure.

The pixel driving circuit PC and the light-emitting element 230 (e.g., light-emitting diode) electrically connected to the pixel driving circuit PC are disposed on the substrate 100. Although it is shown in FIG. 8 that the light-emitting element 230 is the first light-emitting element 230A in an embodiment, the disclosure is not limited thereto. The second light-emitting element 230B and the structure of the pixel driving circuit PC, and the third light-emitting element 230C and the structure of the pixel driving circuit PC are substantially the same as the structure shown in FIG. 8.

As described with reference to FIG. 6A to 6C, the pixel driving circuit PC may include the transistors and the storage capacitor Cst. In an embodiment, for convenience of description, FIG. 8 shows the first transistor T1 and the second transistor T2 among the transistors of the pixel driving circuit PC described with reference to FIG. 6A. In another embodiment, the transistors of the pixel driving circuit PC may include more transistors, as in FIGS. 6B and 6C.

The buffer layer 201 may be disposed between the substrate 100 and the pixel driving circuit PC and may prevent impurities from penetrating the transistor. The buffer layer 201 may include an inorganic insulating material such as silicon oxide, silicon nitride, and silicon oxynitride, and include a single layer or a multi-layer including the above inorganic insulating materials.

The first transistor T1 may include a first semiconductor layer Act1 and a first gate electrode GE1. A source region and a drain region of the first semiconductor layer Act1 may be respectively and electrically connected to a first source electrode SE1 and/or a first drain electrode DE1. The second transistor T2 may include a second semiconductor layer Act2 and a second gate electrode GE2. A source region and a drain region of the second semiconductor layer Act2 may be respectively and electrically connected to a second source electrode SE2 and/or a second drain electrode DE2.

Although FIG. 8 shows a top-gate type in which the first and second gate electrodes GE1 and GE2 are disposed over the first and second semiconductor layers Act1 and Act2 with a gate insulating layer 203 therebetween, the first and second transistors T1 and T2 may be bottom-gate types in another embodiment.

In an embodiment, the first and second semiconductor layers Act1 and Act2 may include polycrystalline silicon. In an embodiment, the first and second semiconductor layers Act1 and Act2 may include amorphous silicon, an oxide semiconductor, or an organic semiconductor. The first and second gate electrodes GE1 and GE2 may include a low-resistance metal material. The first and second gate electrodes GE1 and GE2 may include a conductive material including molybdenum (Mo), aluminum (Al), copper (Cu), and titanium (Ti) and include a single layer or a multi-layer including the above materials.

The gate insulating layer 203 may include an inorganic insulating material such as silicon oxide, silicon nitride, and silicon oxynitride, and include a single layer or a multi-layer including the above-described materials.

The storage capacitor Cst may include the first electrode CE1 and the second electrode CE2 overlapping each other with a first inter-insulating layer 205 therebetween. In an embodiment, the storage capacitor Cst may overlap the first transistor T1. With regard to this, it is shown in FIG. 5 that the first gate electrode GE1 of the first transistor T1 serves as the lower electrode CE1 of the storage capacitor Cst. In another embodiment, the storage capacitor Cst may not overlap the first transistor T1. The storage capacitor Cst may be covered by a second inter-insulating layer 207. The second electrode CE2 of the storage capacitor Cst may include a conductive material including molybdenum (Mo), aluminum (Al), copper (Cu), and titanium (Ti) and have a single-layered structure or a multi-layered structure including the above materials.

The first and second source electrodes SE1 and SE2 and the first and second drain electrodes DE1 and DE2 may be disposed in the same layer, e.g., on the second inter-insulating layer 207. The first and second source electrodes SE1 and SE2 and the first and second drain electrodes DE1 and DE2 may each include a conductive material including molybdenum (Mo), aluminum (Al), copper (Cu), and titanium (Ti) and include a single layer or a multi-layer including the above materials.

The first inter-insulating layer 205 and the second inter-insulating layer 207 may include an inorganic insulating material such as silicon oxide, silicon nitride, and silicon oxynitride, and include a single layer or a multi-layer including the above-described inorganic insulating materials. The first and second transistors T1 and T2 and the storage capacitor Cst may be covered by a first organic insulating layer 209.

A second organic insulating layer 211 and a third organic insulating layer (also referred to as a first insulating layer) 213 may be sequentially disposed on the first organic insulating layer 209. The first organic insulating layer 209, the second organic insulating layer 211, and the third organic insulating layer 213 may include an organic insulating material. The organic insulating material may include a general-purpose polymer such as polymethylmethacrylate (“PMMA”) or polystyrene (“PS”), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, and/or any combinations thereof.

The second voltage line VSSL may be disposed on the second organic insulating layer 211. The first voltage line VDDL may be disposed on the first organic insulating layer 209. In another embodiment, the first voltage line VDDL may be disposed on the second organic insulating layer 211.

The first electrode pad 241 may be disposed on the third organic insulating layer 213. The first electrode pad 241 may be connected to a second contact metal CM2 through the first contact hole CNT1, and the second contact metal CM2 may be connected to a first contact metal CM1 through a third contact hole CNT3.

Although it is shown in FIG. 8 that the first electrode pad 241 is electrically connected to the first transistor T1 through the first and second contact metals CM1 and CM2, the disclosure is not limited thereto. As described with reference to FIGS. 6B and 6C, the pixel driving circuit PC may further include the sixth transistor T6 (FIGS. 6B and 6C), and in this case, the first electrode pad 241 may be electrically connected to the sixth transistor T6 through the first and second contact metals CM1 and CM2. The sixth transistor T6 (FIGS. 6B and 6C) may have substantially the same structure as that of the first transistor T1.

The second electrode pad 242 may be disposed in the same layer as the first electrode pad 241, e.g., disposed on the third organic insulating layer 213. As described above with reference to FIG. 7, the second electrode pad 242 may be electrically connected to the second voltage line VSSL through the second contact hole CNT2. In an embodiment, the second electrode pad 242 may be connected to a third contact metal CM3 through the second contact hole CNT2, and the third contact metal CM3 may be connected to the second voltage line VSSL through a fourth contact hole CNT4. In another embodiment, the second electrode pad 242 may be in direct contact with the second voltage line VSSL through the second contact hole CNT2.

The first electrode pad 241 and the second electrode pad 242 may include metal and/or a conductive oxide. The first electrode pad 241 and the second electrode pad 242 may include a metal material such as silver (Ag), magnesium (Mg), aluminum (Al), platinum (Pt), palladium (Pd), gold (Au), nickel (Ni), neodymium (Nd), iridium (Ir), chrome (Cr), or the like. The first electrode pad 241 and the second electrode pad 242 may include a conductive oxide such as indium tin oxide (“ITO”), indium zinc oxide (“IZO”), zinc oxide (ZnO), indium oxide (In₂O₃), indium gallium oxide (“IGO”), and/or aluminum zinc oxide (“AZO”). The first electrode pad 241 and the second electrode pad 242 may include the metal material and/or a metal material.

The light-emitting element 230 may be an inorganic light-emitting element. In an embodiment, the light-emitting element 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232.

The first semiconductor layer 231 may include a p-type semiconductor layer, for example. The p-type semiconductor layer may include or consist of among semiconductor materials having a composition formula of InₓAl_{y}Ga_{1-x-y}N (0≤x≤1, 0≤y≤1, 0≤x+y≤1), such as GaN, AlN, AlGaN, InGaN, InN, InAlGaN, AlInN, or the like, and may be doped with a p-type dopant such as Mg, Zn, Ca, Sr, or Ba.

The second semiconductor layer 232 may include an n-type semiconductor layer, for example. The n-type semiconductor layer may include or consist of among semiconductor materials having a composition formula of InₓAl_{y}Ga_{1-x-y}N (0≤x≤1, 0≤y≤1, 0≤x+y≤1), such as GaN, AlN, AlGaN, InGaN, InN, InAlGaN, AlInN, or the like, and may be doped with an n-type dopant such as Si, Ge, or Sn.

The intermediate layer 233 is a region in which electrons and holes recombine, and when electrons and holes recombine, they transition to a lower energy level and light having a corresponding wavelength may be created. The intermediate layer 233 may include a semiconductor material having a composition formula of InₓAl_{y}Ga_{1-x-y}N (0≤x≤1, 0≤y≤1, 0≤x+y≤1), and be formed in a single quantum-well structure or a multi quantum-well structure, for example. In addition, the intermediate layer 233 may include a quantum-wire structure or a quantum-dot structure.

Although it is described with reference to FIG. 8 that the first semiconductor layer 231 includes a p-type semiconductor layer and the second semiconductor layer 232 includes an n-type semiconductor layer, the disclosure is not limited thereto. In another embodiment, the first semiconductor layer 231 may include an n-type semiconductor layer, and the second semiconductor layer 232 may include a p-type semiconductor layer.

The first electrode 235 and the second electrode 238 of the light-emitting element 230 may be respectively and electrically connected to the first electrode pad 241 and the second electrode pad 242 through bump metals 250.

The light-emitting element 230 may be electrically connected to the first electrode pad 241 and the second electrode pad 242 by disposing the bump metals 250 on the first electrode pad 241 and the second electrode pad 242, applying preset heat, and then disposing the light-emitting element 230 with preset pressure. In an embodiment, the light-emitting element 230 may be electrically connected to the first electrode pad 241 through a first bump metal 250A between the light-emitting element 230 and the first electrode pad 241. The light-emitting element 230 may be electrically connected to the second electrode pad 242 through a second bump metal 250B between the light-emitting element 230 and the second electrode pad 242. The bump metal 250 may include metal such as gold (Au), nickel (Ni), and indium (In).

The conductive pattern RML may be disposed between the substrate 100 and the first electrode pad 241. In an embodiment, the conductive pattern RML may be disposed on the second organic insulating layer 211. The conductive pattern RML may overlap the connection portion 241n of the first electrode pad 241. In an embodiment, when the connection portion 241n of the first electrode pad 241 is projected in a direction perpendicular to the upper surface of the substrate 100, all of the connection portion 241n of the first electrode pad 241 may overlap with the conductive pattern RML.

The conductive pattern RML may overlap the connection portion 242n of the second electrode pad 242. In an embodiment, when the connection portion 242n of the second electrode pad 242 is projected in a direction perpendicular to the upper surface of the substrate 100, all of the connection portion 242n of the second electrode pad 242 may overlap with the conductive pattern RML.

The conductive pattern RML may include a conductive material including molybdenum (Mo), aluminum (Al), copper (Cu), and titanium (Ti) and be formed in a single layer or a multi-layer including the above materials. The conductive pattern RML may be electrically connected to the second voltage line VSSL through a fifth contact hole CNT5 of the second organic insulating layer (also referred to as a second insulating layer) 211, which is an insulating layer between the second voltage line VSSL and the conductive pattern RML. As described above with reference to FIGS. 6A to 6C, because the second voltage line VSSL is electrically connected to the second electrode pad 242, and the conductive pattern RML is electrically connected to the second voltage line VSSL through the fifth contact hole CNT5, the conductive pattern RML may have the same voltage level as the second electrode pad 242.

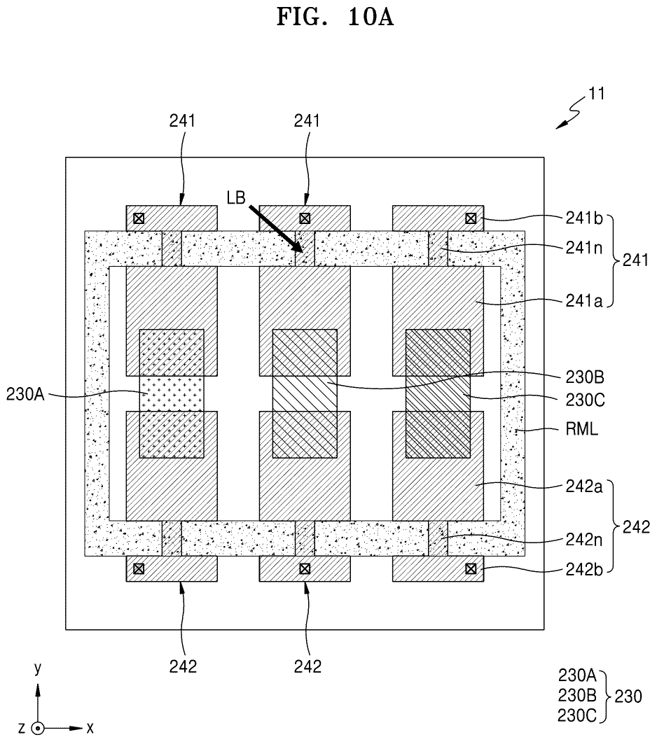

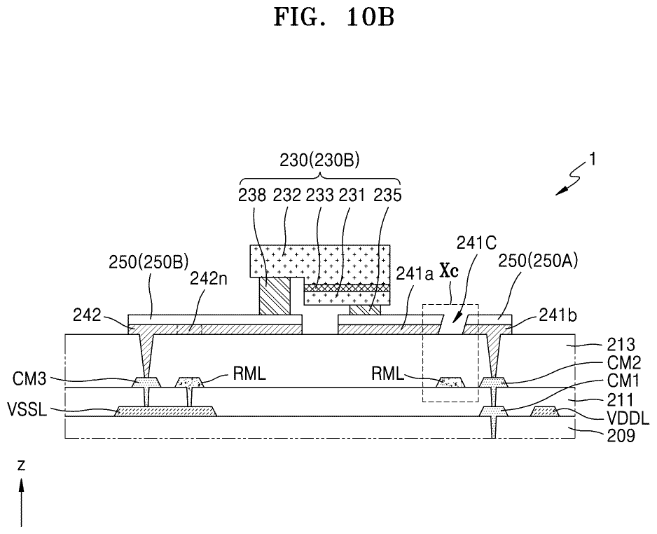

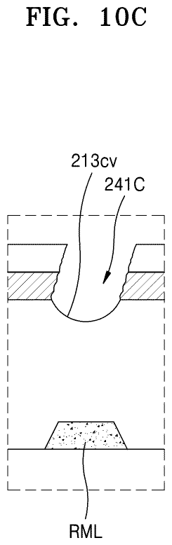

The conductive pattern RML may prevent damage to the pixel driving circuit PC due to a laser used in a repair process described below with reference to FIG. 10A or the like.

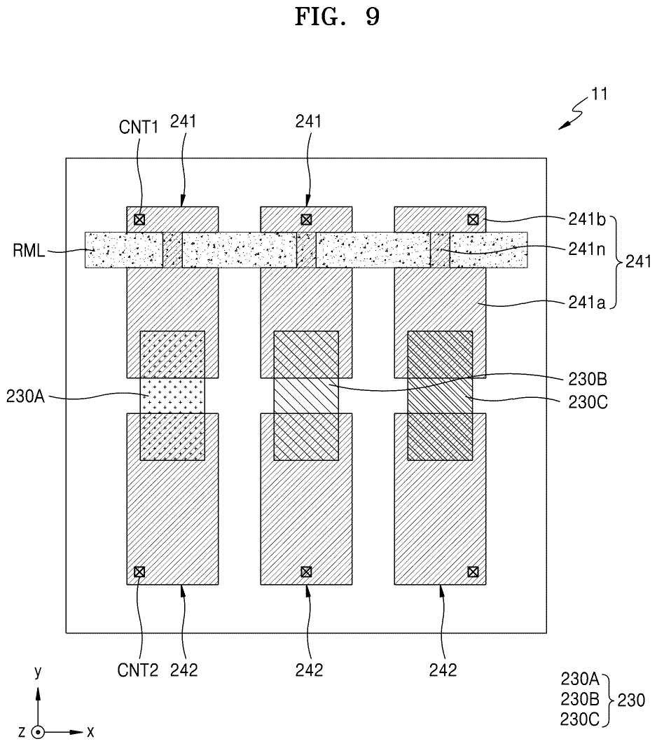

FIG. 9 is an excerpted plan view of an embodiment of a portion of the display area DA (FIG. 3) of the display device 1 according to the disclosure. FIG. 9 shows a planar structure of the first island portion 11 disposed in the display area DA (FIG. 3).

The embodiment shown in FIG. 9 is substantially the same as the structure described above with reference to FIG. 7 and is different in a planar shape of the conductive pattern RML and the second electrode pad 242. The same construction is replaced by the content made above with reference to FIG. 7, and differences are mainly described below.

The conductive pattern RML may have a bar shape. The conductive pattern RML may overlap the connection portion 241n of each of the first electrode pads 241. Each of the second electrode pads 242 may not have the structure described above with reference to FIG. 7, but have a quadrangular shape in which a width thereof (e.g., width in the first direction) is relatively constant as shown in FIG. 9 in another embodiment. In another embodiment, the second electrode pads 242 may be integrally connected.

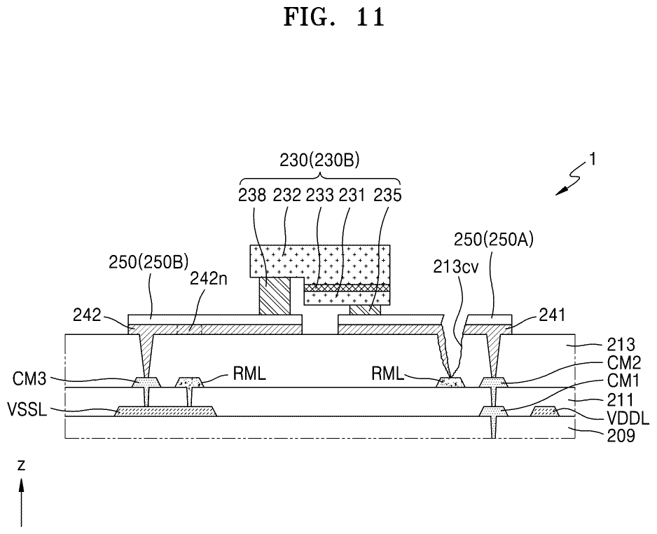

FIG. 10A is a plan view to explain an embodiment of the repair process of the display device 1 according to the disclosure, FIG. 10B is a cross-sectional view of an embodiment of the structure of the display device 1 by the repair process of the display device 1 according to the disclosure, and FIG. 10C is an enlarged view of a region Xc of FIG. 10B. FIG. 11 is a cross-sectional view of an embodiment of the structure of the display device 1 by the repair process of the display device 1 according to the disclosure.

In the manufacturing process of the display device 1, as described above, the bump metals 250 (FIG. 8) are respectively disposed on the first electrode pad 241 and the second electrode pad 242, then preset heat is applied, and the light-emitting elements 230 may be disposed with preset pressure. In the case where defects occur in the arrangement or connection of the light-emitting elements 230 during the arrangement process of the light-emitting elements 230, or in the case where defects occur in an operation of the light-emitting elements 230, a process (hereinafter, also referred to as the repair process) of repairing this may be desired.

The repair process in an embodiment of the disclosure may include a process (e.g., cutting process) of separating the first electrode pad 241 into a plurality of portions by irradiating a laser beam LB to the connection portion 241n of the first electrode pad 241 electrically connected to a defective light-emitting element 230. In an embodiment, in the case where the second light-emitting element 230B is defective among the light-emitting elements 230 shown in FIG. 10A, the laser beam LB may be irradiated to the connection portion 241n of the first electrode pad 241 electrically connected to the second light-emitting element 230B.

The first portion 241a and the second portion 241b of the first electrode pad 241 may be separated and apart from each other by the laser beam LB, as shown in FIG. 10B. Accordingly, the second light-emitting element 230B, which is defective, may be in an off-state. Because the width of the connection portion 241n of the first electrode pad 241 is less than the width of the first portion 241a and/or the second portion 241b, cutting of the first electrode pad 241 using the laser beam LB may be easily performed.

The repair process may include a positive type repair process of removing a defective light-emitting element 230 and disposing a new light-emitting element 230, and a negative type repair process of making a defective light-emitting element 230 be in an off-state. In case of the positive type repair process, all defective light-emitting elements 230 may not be removed during a process of removing the defective light-emitting elements 230, or a defective light-emitting element 230 may be transferred and connected to another portion, and unexpected problems may occur. In contrast, according to the disclosure, as described above, the negative type repair process of making the defective light-emitting element 230B be in an off-state by irradiating the laser beam LB may be performed, and accordingly, problems during the process of removing the defective light-emitting element 230B may be prevented.

By embodiments of the disclosure, because the conductive pattern RML is disposed below the connection portion 241n of the first electrode pad 241 to which the laser beam LB is irradiated, the pixel driving circuit PC may be prevented from being damaged by the laser beam LB used in the repair process.

Depending on the process condition of the repair process, a concave structure (hereinafter, a concave portion) may be formed in an insulating layer (e.g., an insulating layer between the conductive pattern RML and the first electrode pad 241) disposed below a separation region 241C of the first electrode pad 241 that is cut. In an embodiment, as shown in FIG. 10C, the third organic insulating layer 213 disposed under the separation region 241C of the first electrode pad 241 may include a concave portion 213cv. The concave portion 213cv of the third organic insulating layer 213 may overlap the conductive pattern RML thereunder, and the bottom surface of the concave portion 213cv may be spaced apart from the upper surface of the conductive pattern RML.

In another embodiment, in the repair process, the concave portion 213cv of the third organic insulating layer 213 may extend up to the upper surface of the conductive pattern RML, as shown in FIG. 11.

In an embodiment, due to heat and energy of the laser beam LB, the first portion 241a or the second portion 241b of the first electrode pad 241 may melt and be in direct contact with the upper surface of the conductive pattern RML through the concave portion 213cv. With regard to this, it is shown in FIG. 11 that the first portion 241a of the first electrode pad 241 is electrically connected to the conductive pattern RML. The first portion 241a of the first electrode pad 241 electrically connected to the light-emitting element 230 (e.g., the second light-emitting element 230B) may be electrically connected to the second voltage line VSSL, which is the same voltage level as the second electrode pad 242.

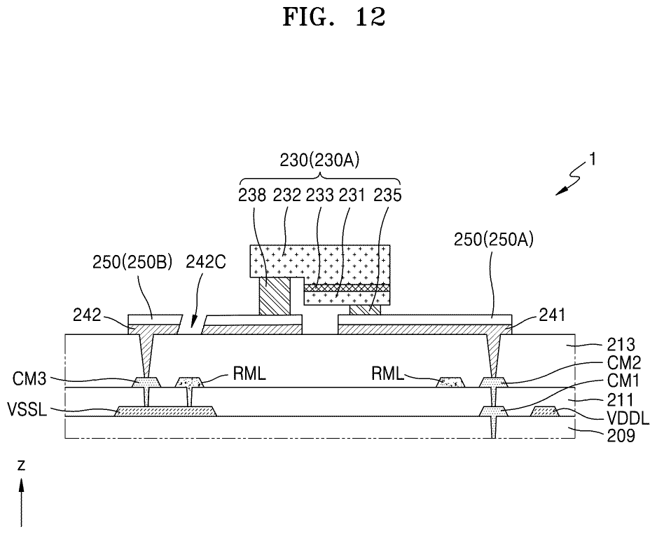

Although it is described with reference to FIGS. 10A to 10C and 11 that the laser beam LB is irradiated to the first electrode pad 241 during the repair process, the disclosure is not limited thereto. In another embodiment, as described below in FIG. 12, the laser beam LB may be irradiated to the second electrode pad 242.

FIG. 12 is a schematic cross-sectional view of an embodiment of the display device 1 by the repair process of the display device 1 according to the disclosure.

During the repair process, the laser beam LB (FIG. 10A) may be irradiated to the connection portion 242n (FIG. 10A) of the second electrode pad 242, and in this case, the second electrode pad 242 may include a separation region 242C as shown in FIG. 12. The first portion 242a and the second portion 242b of the second electrode pad 242 may be apart and separated from each other around the separation region 242C, and the light-emitting element 230 that is defective may be in an off-state.

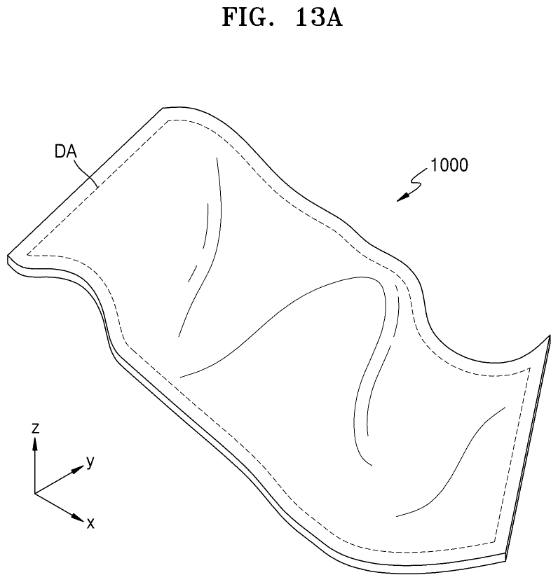

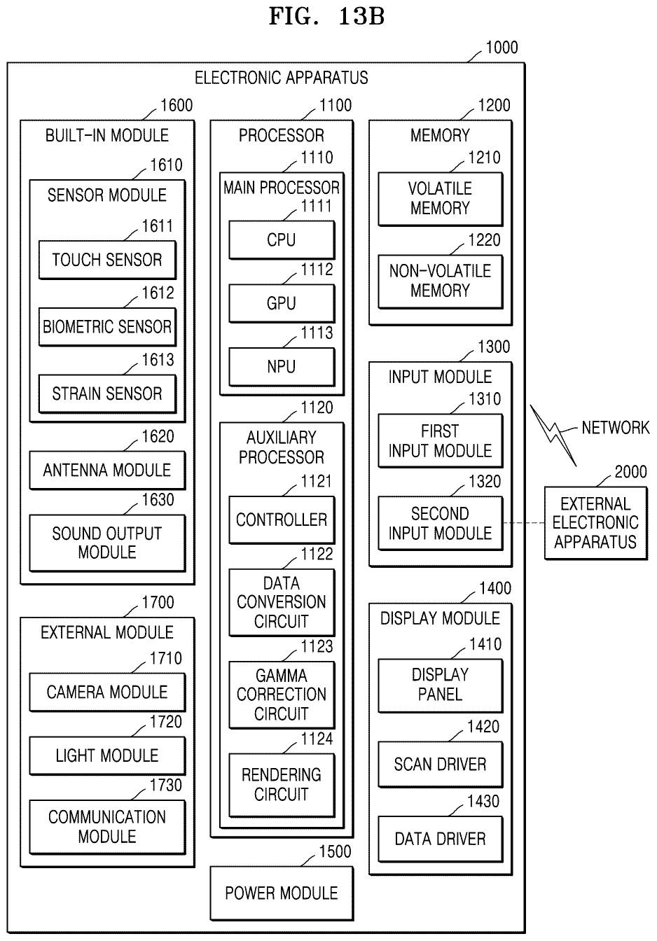

FIG. 13A is a schematic perspective view of an embodiment of an electronic apparatus 1000 including the display device according to the disclosure, and FIG. 13B is a schematic block diagram of the electronic apparatus 1000 including the display device 1 according to the disclosure.

Referring to FIG. 13A, the electronic apparatus 1000 is freely transformed three-dimensionally, and may provide a three-dimensional image surface through the display area DA. When the electronic apparatus 1000 is freely transformed three-dimensionally, it is distinguished from an operation of an electronic apparatus having a rollable display device such as a case where a portion of a rolled-up display area is visible to a user and then another portion of the rolled-up display area is unfolded so that the entirety of the display area is visible to the user (or a case where the entirety of the unfolded display area is visible to the user and then the display area is rolled-up so that only a portion of the display area is visible to the user). The electronic apparatus 1000 in embodiments of the disclosure may represent transformation such as a case where the area of the entirety of the display area DA increases or decreases again while the electronic apparatus 1000 is transformed in the x direction, y direction, and/or z direction.

Referring to FIG. 13B, the electronic apparatus 1000 may include a processor 1100, a memory 1200, an input module 1300, a display module 1400, a power module 1500, a built-in module 1600, and an external module 1700. In an embodiment, in the electronic apparatus 1000, at least one of the elements may be omitted, or one or more other elements may be added. In an embodiment, some (e.g., the built-in module 1600) of the elements may be integrated into another element (e.g., the display module 1400).

The processor 1100 may control at least one other element (e.g., a hardware or software element) of the electronic apparatus 1000 connected to the processor 1100 by executing software, and perform various data processes or operations. In an embodiment, as at least some of data processes or operations, the processor 1100 may store commands or data received from another element (e.g., the input module 1300, a sensor module 1610, or a communication module 1730) in a volatile memory 1210, process the commands or data stored in the volatile memory 1210, and store result data in a non-volatile memory 1220.

The processor 1100 may include a main processor 1110 and an auxiliary processor 1120. The main processor 1110 may include at least one of a central processing unit (“CPU”) 1111 and an application processor (“AP”). The main processor 1110 may further include at least one of a graphics processing unit (“GPU”) 1112, a communication processor (“CP”), and an image signal processor (“ISP”). The main processor 1110 may further include a neural processing unit (“NPU”) 1113. The NPU is a processor specialized in processing artificial intelligence models, and the artificial intelligence models may be created through machine learning. The artificial intelligence models may include a plurality of artificial neural network layers. The artificial neural network may be one of a deep neural network (“DNN”), a convolutional neural network (“CNN”), a recurrent neural network (“RNN”), a restricted Boltzmann machine (“RBM”), a deep belief network (“DBN”), a bidirectional recurrent deep neural network (“BRDNN”), a deep Q-network, and a combination of two or more of the above, but is not limited to the examples described above. The artificial intelligence models may additionally or alternatively include a software structure in addition to a hardware structure. At least two of the processing units and the processors may be implemented as one integrated construction (e.g., a single chip) or respectively implemented as independent constructions (e.g., a plurality of chips).

The auxiliary processor 1120 may include a controller 1121. The controller 1121 may include an interface conversion circuit and a timing control circuit. The controller 1121 receives image signals from the main processor 1110, converts a data format of image signals to match interface specifications of the display module 1400, and outputs image data. The controller 1121 may output various kinds of control signals desired for driving the display module 1400.

The auxiliary processor 1120 may further include a data processing circuit such as a data conversion circuit 1122, a gamma correction circuit 1123, and a rendering circuit 1124. The data conversion circuit 1122 may receive image data from the controller 1121, correct image data such that images are displayed at desired brightness according to characteristics of the electronic apparatus 1000, a user's settings, or the like, or convert image data to reduce power consumption or compensate for an afterimage. The gamma correction circuit 1123 may convert image data, a gamma reference voltage, or the like such that images displayed by the electronic apparatus 1000 have desired gamma characteristics. The rendering circuit 1124 may receive image data from the controller 1121, and render the image data by taking into account the pixel configuration of the display device 1 applied to the electronic apparatus 1000. At least one of the data conversion circuit 1122, the gamma correction circuit 1123, and the rendering circuit 1124 may be integrated into another element (e.g., the main processor 1110 or the controller 1121). In an embodiment, the auxiliary processor 1120 may be integrated into a data driver 1430.

The memory 1200 may store various data and input data or output data for commands related thereto, where the various data is used by at least one element (e.g., the processor 1100 or the sensor module 1610) of the electronic apparatus 1000. The memory 1200 may include at least one of the volatile memory 1210 and the non-volatile memory 1220.

The input module 1300 may receive commands or data from the outside (e.g., a user or an external electronic apparatus 2000) of the electronic apparatus 1000, where the commands or data are to be used by the element (e.g., the processor 1100, the sensor module 1610, or a sound output module 1630) of the electronic apparatus 1000.

The input module 1300 may include a first input module 1310 to which commands or data from a user are input, and a second input module 1320 to which commands or data from the external electronic apparatus 2000 are input.

The first input module 1310 may include a microphone, a mouse, a keyboard, or a pen (e.g., a passive pen or active pen). The first input module 1310 may include a mechanical input means such as buttons, a dome switch, a jog wheel, a jog switch, or the like, or a touch input means disposed on the lower surface or the lateral surface of the electronic apparatus 1000. The touch input means may include the touchscreen layer of the display device 1.

The second input module 1320 may be connected to various kinds of external electronic apparatuses 2000 connected to the electronic apparatus 1000 via wires or wirelessly. In an embodiment, the second input module 1320 may include a high definition multimedia interface (“HDMI”), a universal serial bus (“USB”) interface, a secure digital (“SD”) card interface, or an audio interface. The second input module 1320 may include a connector that may physically connect the electronic apparatus 1000 to the external electronic apparatus 2000, where the connector includes an HDMI connector, a USB connector, an SD card connector, or an audio connector (e.g., a headphone connector). The electronic apparatus 1000 may perform appropriate control related to the connected external electronic apparatus 2000 in response to the external electronic apparatus 2000 being connected to the second input module 1320.

The display module 1400 provides a user with visual information. The display module 1400 may include the display device 1, a scan driver 1420, and the data driver 1430.

The display device 1 displays (outputs) information processed by the electronic apparatus 1000. The display device 1 may display execution screen information of an application driven in the electronic apparatus 1000, or user interface (“UI”) and graphic UI (“GUI”) information corresponding to the execution screen information.

The scan driver 1420 may be disposed (e.g., mounted) on the display device 1 as a driving chip. In an alternative embodiment, the scan driver 1420 may be directly formed on the display device 1. In an embodiment, the scan driver 1420 may include an amorphous silicon thin-film transistor (“TFT”) gate driver circuit (“ASG”), a low temperature polycrystalline silicon (“LTPS”) TFT gate driver circuit, or an oxide semiconductor TFT gate (“OSG”) driver circuit embedded in the display device 1. The scan driver 1420 receives control signals from the controller 1121 and outputs scan signals to the display device 1 in response to control signals.

The display device 1 may further include an emission control driver. The emission control driver outputs an emission control signal to the display device 1 in response to a control signal received from the controller 1121. The emission control driver may be formed separately from the scan driver 1420 or integrated in the scan driver 1420.

The data driver 1430 receives a control signal from the controller 1121, converts image data into a data voltage in the form of an analog voltage in response to a control signal, and outputs data voltages to the display device 1.

The data driver 1430 may be integrated into some elements of the auxiliary processor 1120. In an embodiment, the data driver 1430 may be provided in a timing controller embedded driver integrated circuit (“IC”) including the controller 1121.

The power module 1500 supplies power to the elements of the electronic apparatus 1000. The power module 1500 may include a battery charging a power voltage. In addition, the power module 1500 has a connection port, and the connection port may be included in the second input module 1320 to which an external charger that supplies power to charge the battery is connected. In an alternative embodiment, the power module 1500 may include a wireless power transmission/reception member to charge the battery wirelessly. The wireless power transmission/reception member may include a plurality of coil-shaped antenna radiators. The power module 1500 may include a power management IC (“PMIC”). The PMIC supplies power optimized for each of the elements of the electronic apparatus 1000.

The electronic apparatus 1000 may further include the built-in module 1600 and the external module 1700. The built-in module 1600 may include the sensor module 1610, an antenna module 1620, and the sound output module 1630. The external module 1700 may include a camera module 1710, a light module 1720, and/or the communication module 1730.

The sensor module 1610 may include touch electrodes of the touchscreen layer of the display device 1, and the touch sensor driver. The sensor module 1610 may sense an input due to a user's body or an input due to a pen, and generate an electrical signal or a data value corresponding to the input. The sensor module 1610 may include at least one of a touch sensor 1611, a biometric sensor 1612, and a strain sensor 1613.

The touch sensor 1611 may generate a data value corresponding to coordinate information of an input due to a user's body (e.g., fingers or the like) or an input due to a pen. The touch sensor 1611 may generate, as data values, changes in electrostatic capacity, pressure, or electromagnetism due to an input.

The biometric sensor 1612 may generate data values that recognize a portion of the user's body (e.g., fingerprints, irises, face, or the like) or generate data values corresponding to body information (e.g., blood pressure, moisture, heart rate, body composition, or the like). The biometric sensor 1612 may use an optical method, an ultrasonic method, or a capacitive method.

The strain sensor 1613 may include layers, patterns or wirings in which a measurable physical quantity changes according to the stretching of the display device 1. In an embodiment, the strain sensor 1613 may include wirings in which a pressure, a resistance, and/or a capacitance changes due to the stretching of the display device 1. In another embodiment, the strain sensor 1613 may include optical layers or optical patterns in which a transmittance and/or reflectivity changes due to the stretching of the display device 1.

The electronic apparatus 1000 may improve the quality of images implemented by the display device 1 or control the display device 1 based on physical quantity changes due to the stretching of the display device 1 measured by the strain sensor 1613. Control operations of the display device 1 may include operations such as displaying an operation image for protecting the display device 1, blocking voltages for driving the display device 1 (e.g., display panel 1410 in FIG. 13B or display module 1400 in FIG. 13B), or stopping a stretching operation of the display device 1.

In an embodiment, at least one of the touch sensor 1611, the biometric sensor 1612, and the strain sensor 1613 may be built into the display device 1. In an embodiment, at least one of the touch sensor 1611, the biometric sensor 1612, and the strain sensor 1613 may be formed during a process that is successive to the process of forming the pixel driving circuit and/or the light-emitting element of the display device 1. Accordingly, the display device 1 may serve as one of the input modules 1300 that provide an input interface between the electronic apparatus 1000 and a user, and simultaneously, serve as the display module 1400 that provides an output interface between the electronic apparatus 1000 and a user.

In an embodiment, at least two of the touch sensor 1611, the biometric sensor 1612, and the strain sensor 1613 may be integrated in one sensing panel through the same process. In an embodiment, although the sensing panel may be disposed between the display device 1 and a window cover disposed on a front surface of the display device 1, the disclosure is not limited thereto.

The antenna module 1620 may include at least one antenna for transmitting signals or power to the outside or receiving signals or power from the outside. In an embodiment, the communication module 1730 may transmit signals to an external electronic apparatus or receive signals from an external electronic apparatus through an antenna suitable for a communication method. An antenna pattern of the antenna module 1620 may be integrated in one element (e.g., the display device 1) of the display module 1400 or the biometric sensor 1612.

The sound output module 1630 is a device for outputting sound signals to the outside of the electronic apparatus 1000, and may output sound data received from the communication module 1730 or stored in the memory 1200 during call signal reception, a communication mode or recording mode, a voice recognition mode, a broadcasting reception mode, or the like. The sound output module 1630 may output sound signals related to a function (e.g., a call signal reception tone, a message reception tone, or the like) performed by the electronic apparatus 1000. The sound output module 1630 may include a receiver and a speaker. At least one of the receiver and the speaker may be a sound generator that is attached on the backside of the display device 1 and vibrates the display device 1 to output sounds. The sound generator may be a piezoelectric element or a piezoelectric actuator that contracts and expands according to electrical signals, or an exciter that generates magnetic force by a voice coil to vibrate the display device 1.

The camera module 1710 may capture still images and moving images. In an embodiment, the camera module 1710 may include at least one lens, an image sensor, or an image signal processor. The camera module 1710 may further include an infrared camera that may measure whether a user is present, a user's position, a user's gaze, or the like.

The light module 1720 may output signals for informing occurrence of an event using light of a light source, or provide light to obtain images. Here, embodiments of event occurrence include message reception, call signal reception, a missed call, an alarm, a calendar reminder, receiving an email, being notified of battery charge information, or the like. The light module 1720 may include a light-emitting diode or a xenon lamp. The light module 1720 may emit light of a single color or multiple colors to the front side or backside of the electronic apparatus 1000. The light module 1720 may operate in cooperation with the camera module 1710 or independently.

The communication module 1730 may establish a wired or wireless communication channel between the electronic apparatus 1000 and the external electronic apparatus 2000, and perform communication through the established communication channel. The communication module 1730 may include one or both of a wireless communication module, such as a cellular communication module, a short-range wireless communication module, or a global navigation satellite system (“GNSS”) communication module, and a wired communication module, such as a local area network (“LAN”) communication module, or a power line communication module. The communication module 1730 may transmit and receive wireless signals on the Internet using at least one of a wireless LAN) (“WLAN”), wireless-fidelity (“Wi-Fi”), Wi-Fi direct, and digital living network alliance (“DLNA”) technologies. In addition, the communication module 1730 may support short-range communication using at least one of Bluetooth™, RFID radio frequency identification (“RFID”), infrared data association (“IrDA”), ultra wideband (“UWB”), ZigBee, near field communication (“NFC”), Wi-Fi, Wi-Fi Direct, and wireless USB technologies. The above-described various kinds of communication modules 1730 may be implemented in one chip or respectively implemented as separate chips.

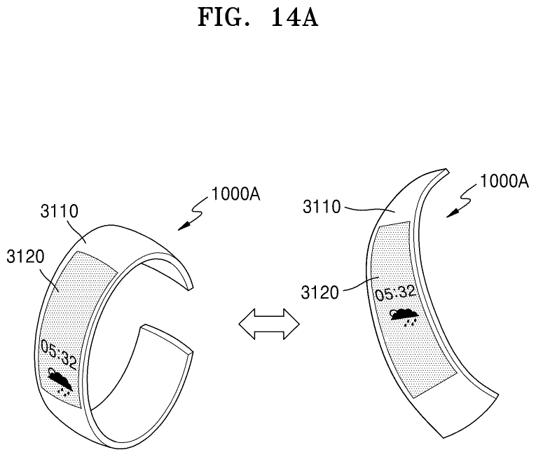

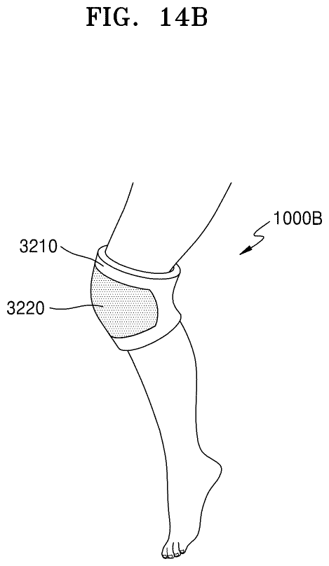

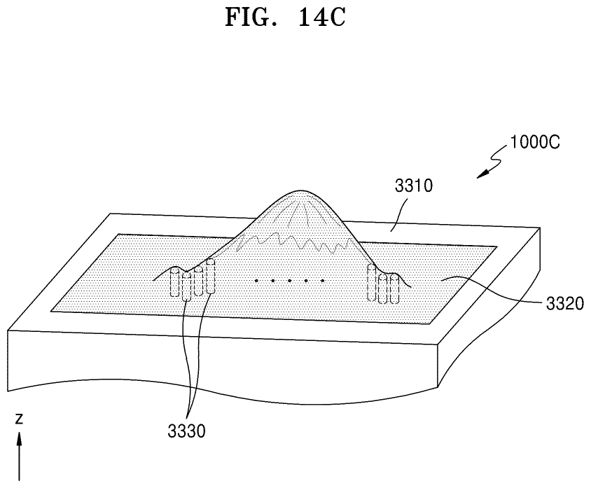

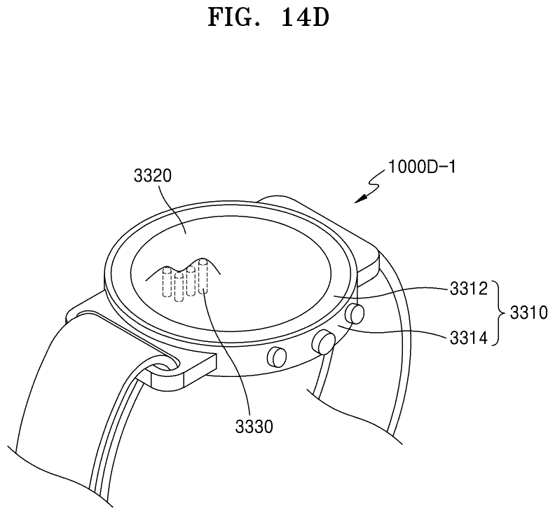

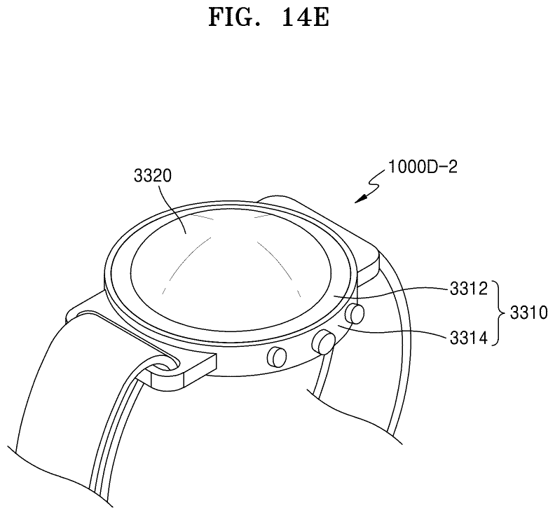

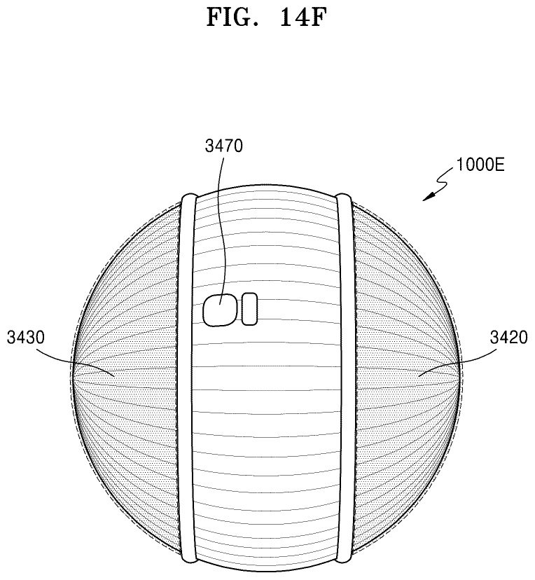

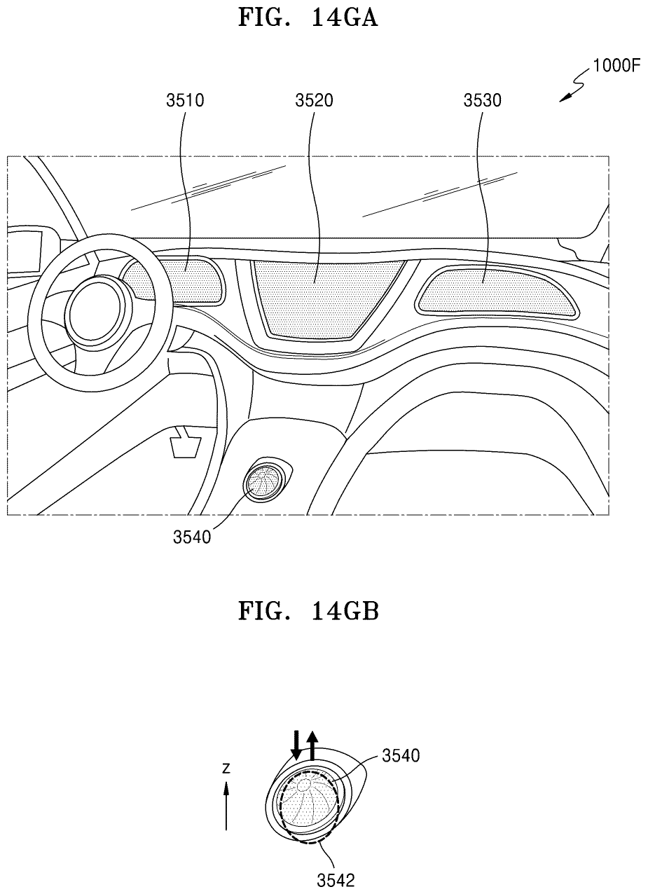

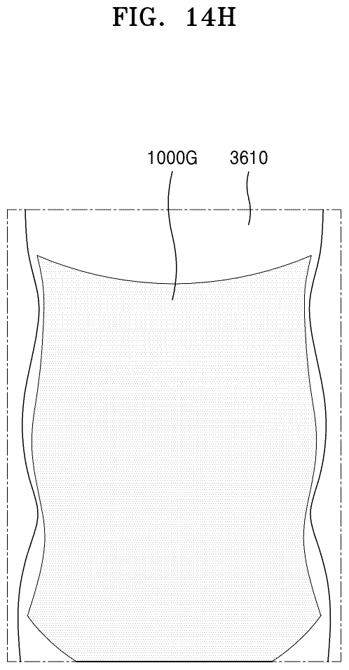

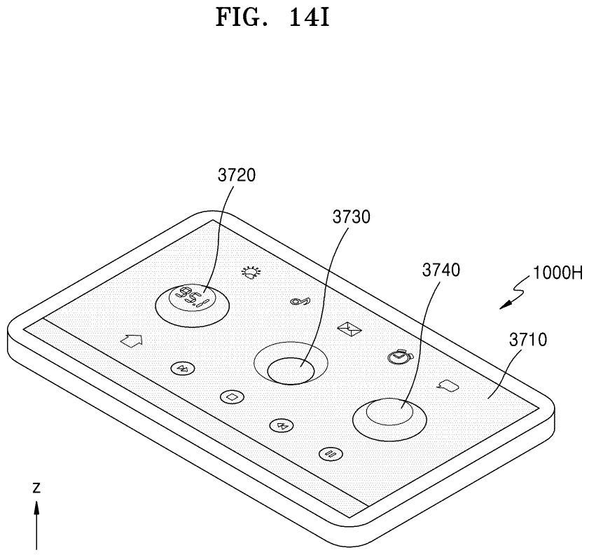

FIGS. 14A to 14I are respectively schematic perspective views of an embodiment of an electronic apparatus including a display device according to the disclosure.

Referring to FIG. 14A, the display device in an embodiment of the disclosure may be utilized in a wearable electronic apparatus 1000A that may be worn on a portion of a user's body. The wearable electronic apparatus 1000A may include a body portion 3110 and a display portion 3120 provided to the body portion 3110. The display device in embodiments may be used as the display portion 3120 of the wearable electronic apparatus 1000A. As shown in FIG. 14A, the wearable electronic apparatus 1000A may be transformed. In an embodiment, the wearable electronic apparatus 3100 may be used as a smartwatch or a smartphone according to a user's selection.

FIG. 14B shows a medical electronic apparatus 1000B. In an embodiment, the medical electronic apparatus 1000B may include a body portion 3210 and a light-emitting portion 3220. The display device in embodiments of the disclosure may be used as the display portion 3220 of the medical electronic apparatus 1000B. The light-emitting portion 3220 may emit light (e.g., infrared rays, visible rays, or the like) in a preset wavelength band to a patient's body. In an embodiment, the body portion 3210 may include a stretchable fiber material and have a structure that may be worn on the body of a user.

FIG. 14C shows an educational electronic apparatus 1000C. In an embodiment, the educational electronic apparatus may include a display portion 3320 provided inside a housing 3310. The display portion 3320 may be used as the display device in the embodiments of the disclosure. An image such as a sea with crashing waves, a snow-covered mountain, or a volcano with flowing lava may be provided through the display portion 3320, and in this case, the display portion 3320 may be stretched in a height direction (e.g., z direction) to reflect the height of the wave, mountain, or volcano. In an embodiment, a portion of the display portion 3320 may sequentially change its height in a direction in which the lava flows, thereby showing the movement of the lava three dimensionally. The educational electronic apparatus 1000C may include a plurality of pins 3330 (or a stroke portion) disposed on the rear surface of the display portion 3320 such that the display portion 3320 is stretched in the height direction. The pins 3330 may be implemented to move in the third direction (e.g., z direction or −z direction) such that an image expressed on the display portion 3320 has a height three dimensionally. Although FIG. 14C describes the educational electronic apparatus 1000C, the purpose thereof is not limited thereto as far as the educational electronic apparatus provides preset image information.

FIGS. 14D and 14E show the display device is used in wearable electronic apparatuses 1000D-1 and 1000D-2 such as a smartwatch.

In an embodiment, as shown in FIG. 14D, because the display device corresponding to the display portion 3320 of the electronic apparatus 1000D-1 is stretchable three-dimensionally, the display panel may provide, to a user, various haptic information in addition to visual information through images. In an embodiment, the electronic apparatus 1000D-1 may provide haptic information, such as Braille display for the visually impaired or tactile stimulation linked to an image, by a plurality of pins 3330 (or stroke portions) disposed below the display portion 3320. Because the display panel forming the display portion 3320 is stretchable three-dimensionally, the display device may provide the haptic information to a user. The electronic apparatus 1000D-1 may include the body portion 3310, where the body portion 3310 includes a housing 3314 in which the display device forming the display portion 3320 and the pins 3330 (or stroke portions) are accommodated, and a frame 3312 that may be coupled to the housing 3314 with the display device therebetween. In an embodiment, the frame 3312 may be unitary with the housing 3314.

The electronic apparatus 1000D-2 of FIG. 14E may include the body portion 3310 and the display portion 3320 accommodated in the body portion 3310 and providing visual information as in FIG. 14D. In an embodiment, because the display device corresponding to the display portion 3320 is stretchable three-dimensionally, the display panel may include the display portion 3320 of a dome shape. In an embodiment, the display device may be assembled to the body frame of a dome shape during the process of manufacturing the electronic apparatus 1000D-2, and in this case, because the display device is stretchable three-dimensionally, the display device may be assembled while being stretched along the shape of the hemispherical body frame.

FIG. 14F shows an embodiment of an electronic apparatus 1000E according to the disclosure includes a robot. The robot may recognize a movement or object using a camera module 3470 and display preset images to a user through display portions 3420 and 3430.

In an embodiment, because the display device in an embodiment of the disclosure may be stretched in various directions as described above, the display device may be assembled to the body frame having a hemispherical shape, and thus, the robot may include the display portions 3420 and 3430 of a hemispherical shape.

FIG. 14GA shows an embodiment of a vehicle display device 1000F as an electronic apparatus according to the disclosure, and FIG. 14GB is an enlarged view of a portion of FIG. 14GA. The vehicle display device 1000F may include a cluster 3510, a center information display (“CID”) 3520, and/or a co-driver display 3530. Because the display device in an embodiment may be stretched in various directions, the display device may be used in the cluster 3510, the CID 3520, and/or the co-driver display 3530 without being restricted by the shape of an internal frame of the vehicle.

Although it is shown in FIG. 14GA that the cluster 3510, the CID 3520, and/or the co-driver display 3530 are separated from each other, the disclosure is not limited thereto. In another embodiment, two or more selected from the cluster 3510, the CID 3520, and the co-driver display 3530 may be integrally connected.

In an embodiment, the vehicle display device 1000F may include a button 3540 that may express preset images. Referring to an enlarged view of FIG. 14GB, the button 3540 of a hemispherical shape may include an object 3542 and a display device disposed on the object 3542, where the object 3542 provides the feel of a button while moving in the z direction or-z-direction. In an embodiment, in the case where the object 3542 has a three-dimensionally round surface, the display device may also have a three-dimensionally round surface.

FIG. 14H shows an electronic apparatus in an embodiment of the disclosure is an electronic apparatus 1000G for advertising or display. In an embodiment, the electronic apparatus 1000G for advertising or display may be installed on a fixed structure 3610 such as a wall or pole. In the case where the structure 3610 includes an uneven surface as shown in FIG. 14H, the electronic apparatus 1000G for advertising or display may be also disposed along the uneven surface of the structure 3610. In an embodiment, the electronic apparatus 1000G for advertising or display may be installed on the structure 3610 using a heat shrink film.

FIG. 14I shows an electronic apparatus 1000H in an embodiment of the disclosure is a controller. The controller may include an image-type button. In an embodiment, the controller may include first to third button regions 3720, 3730, and 3740 in which a portion of the display portion 3710 protrudes in the z direction or protrudes in the-z direction (or is recessed in the z direction). In an embodiment, the first and third button regions 3720 and 3740 may protrude in the z direction, and the second button region 3730 may protrude in the −z direction (or be recessed in the z direction).

While the disclosure has been described with reference to an embodiment shown in the drawings, it will be understood by those of ordinary knowledge in the art that these are just examples and various changes and equivalent other embodiments may be made therefrom. Accordingly, the true technical scope of the disclosure should be defined by the spirit of the appended claims.

1. A display device comprising:
a substrate;
a first electrode pad and a second electrode pad apart from each other on the substrate;
a first light-emitting element on the first electrode pad and the second electrode pad, the first light-emitting element electrically connected to the first electrode pad and the second electrode pad;
a conductive pattern between the substrate and the first electrode pad; and
a first insulating layer between the conductive pattern and the first electrode pad,
wherein a portion of the first electrode pad overlaps the conductive pattern, and a width of the portion of the first electrode pad is less than a width of a first portion of the first electrode pad overlapping the first light-emitting element.

2. The display device of claim 1, wherein the conductive pattern has a same voltage level as a voltage level of the second electrode pad.

3. The display device of claim 2, further comprising:
a common voltage line on the substrate and electrically connected to the second electrode pad; and
a second insulating layer between the common voltage line and the conductive pattern,
wherein the common voltage line is electrically connected to the conductive pattern through a contact hole defined in the second insulating layer.

4. The display device of claim 1, wherein a portion of the second electrode pad overlaps the conductive pattern, and a width of the portion of the second electrode pad is less than a width of a first portion of the second electrode pad.

5. The display device of claim 1, further comprising:
a transistor on the substrate;
another first electrode pad next to the first electrode pad;
another second electrode pad apart from the another first electrode pad; and
a second light-emitting element on the another first electrode pad and the another second electrode pad, the second light-emitting element electrically connected to the another first electrode pad and the another second electrode pad,
wherein the another first electrode pad includes:
a first portion overlapping the second light-emitting element; and
a second portion electrically connected to the transistor, and
wherein the first portion and the second portion of the another first electrode pad are separated from each other.

6. The display device of claim 5, wherein the second light-emitting element is in an off-state.

7. The display device of claim 6, wherein a portion of the first insulating layer corresponding to a separation region between the first portion and the second portion of the another first electrode pad includes a concave portion.

8. The display device of claim 7, wherein a bottom surface of the concave portion is spaced apart from an upper surface of the conductive pattern.

9. The display device of claim 7, wherein the concave portion extends up to an upper surface of the conductive pattern, and the first portion or the second portion of the another first electrode pad is in direct contact with the upper surface of the conductive pattern.

10. A repairing method of a display device comprising a transistor on a substrate, a first electrode pad electrically connected to the transistor, a second electrode pad apart from the first electrode pad, a light-emitting element disposed on the first electrode pad and the second electrode pad and electrically connected to the first electrode pad and the second electrode pad, a conductive pattern between the substrate and the first electrode pad, and a first insulating layer between the conductive pattern and the first electrode pad, the method comprising:
irradiating a laser to a portion of the first electrode pad in a manner in which a first portion of the first electrode pad electrically connected to the light-emitting element and a second portion of the first electrode pad electrically connected to the transistor are separated from each other.

11. The method of claim 10, wherein a width of the portion of the first electrode pad to which the laser is irradiated is less than a width of the first portion of the first electrode pad.

12. The method of claim 10, wherein, in the irradiating the laser, the portion of the first electrode pad overlaps the conductive pattern.

13. The method of claim 10, wherein, in the irradiating the laser, a width of the portion of the first electrode pad is less than a width of the first portion or a width of the second portion of the first electrode pad.

14. The method of claim 10, wherein the conductive pattern has a same voltage level as a voltage level of the second electrode pad.

15. An electronic apparatus including:
a display device comprising:
a first electrode pad and a second electrode pad apart from each other over a substrate;
a first light-emitting element on the first electrode pad and the second electrode pad and electrically connected to the first electrode pad and the second electrode pad;
a conductive pattern between the substrate and the first electrode pad; and
a first insulating layer between the conductive pattern and the first electrode pad,
wherein a width of a portion of the first electrode pad is less than a width of a first portion of the first electrode pad overlapping the first light-emitting element.

16. The electronic apparatus of claim 15, wherein the conductive pattern has a same voltage level as a voltage level of the second electrode pad.

17. The electronic apparatus of claim 16, wherein the display device further comprises:
a common voltage line disposed on the substrate and electrically connected to the second electrode pad; and
a second insulating layer between the common voltage line and the conductive pattern,
wherein the common voltage line is electrically connected to the conductive pattern through a contact hole defined in the second insulating layer.

18. The electronic apparatus of claim 16, wherein the portion of the first electrode pad overlaps the conductive pattern.

19. The electronic apparatus of claim 16, wherein the display device further comprises:
a transistor disposed on the substrate;
another first electrode pad next to the first electrode pad;
another second electrode pad apart from the another first electrode pad; and
a second light-emitting element on the another first electrode pad and the another second electrode pad, the second light-emitting element electrically connected to the another first electrode pad and the another second electrode pad,
wherein the another first electrode pad includes:
a first portion overlapping the second light-emitting element; and
a second portion electrically connected to the transistor, and
wherein the first portion and the second portion of the another first electrode pad are separated from each other.

20. The electronic apparatus of claim 19, wherein a portion of the first insulating layer corresponding to a separation region between the first portion and the second portion of the another first electrode pad includes a concave portion.
